(19) United States
(12) Patent Application Publication
(10) Pub. No.: US 2026/0293401 A1
(43) Pub. Date: Sep. 24, 2026

(54) DISPLAY DEVICE INCLUDING SUB-PIXEL GROUPS AND ELECTRONIC DEVICE INCLUDING THE DISPLAY DEVICE

(71) Applicant: SAMSUNG DISPLAY CO., LTD., Yongin-si (KR)

(72) Inventors: Byeong Hee WON, Yongin-si (KR); Eun Kyoung NAM, Yongin-si (KR); Hyun Jin CHO, Yongin-si (KR)

(21) Appl. No.: 19/380,032

(22) Filed: Nov. 5, 2025

(30) Foreign Application Priority Data
Mar. 19, 2025 (KR) 10-2025-0035117

(51) Int. Cl. H10H 29/49; H10H 29/855

(52) U.S. Cl. CPC H10H 29/49; H10H 29/855

(57) ABSTRACT

A display device including a display driver configured to output an image data voltage, a display panel including a plurality of sub-pixels, and configured to receive the image data voltage and to emit light, and a lens assembly including a plurality of lenses and a lens boundary portion disposed between the plurality of lenses. The image data voltage includes a first data voltage group supplying a first data voltage to a first sub-pixel group of the plurality of sub-pixels, respectively, the first sub-pixel group is configured to emit light passing through the plurality of lenses. The image data voltage includes a second data voltage group supplying a second data voltage to a second sub-pixel group of the plurality of sub-pixels, respectively, the second sub-pixel group is configured to emit light passing through the lens boundary portion. The second data voltage is different from the first data voltage. .

### CROSS-REFERENCE TO RELATED APPLICATION

This U.S. non-provisional patent application claims priority under 35 U.S.C. §119 to Korean Patent Application No. 10-2025-0035117 filed on Mar. 19, 2025, in the Korean Intellectual Property Office, the entire disclosure of which is incorporated by reference herein.

### TECHNICAL FIELD

The present disclosure relates to a display device and, more particular to, a display device including sub-pixel groups and an electronic device including the display device.

### DISCUSSION OF THE RELATED ART

As the communication technology and the media develop, display devices that display images in various applications and environments including portable electronics, large-area televisions, and vehicle displays are gaining widespread usage. In particular, various types of display devices such as liquid crystal displays (LCDs) and organic light emitting displays (OLEDs) have been widely used.

For example, a stereoscopic image display device configured to divide and display an image onto a spatial region in front of the display device using a lens array has been developed. For example, the stereoscopic image display device includes a binocular parallax-type stereoscopic image display device configured to separate and display a left-eye image and a right-eye image to generate a three-dimensional effect based on binocular parallax. For example, the stereoscopic image display device includes a light field-type stereoscopic image display device configured to converge light emitted from each lens of a lens array onto a view area corresponding to observation positions of a viewer. Accordingly, research into the light field-type stereoscopic image display device has been actively pursued to implement enhanced three-dimensional (3D) images by increasing the number of view regions and improving angular resolution.

### SUMMARY

According to various embodiments of the present disclosure, a display device includes a display driver configured to output an image data voltage, a display panel including a plurality of sub-pixels, and configured to receive the image data voltage and to emit light, and a lens

assembly including a plurality of lenses and a lens boundary portion disposed between the plurality of lenses, where the plurality of lenses is configured to refract the emitting light. The image data voltage includes a first data voltage group supplying a first data voltage to a first sub-pixel group of the plurality of sub-pixels, respectively, where the first sub-pixel group is configured to emit light passing through the plurality of lenses. The image data voltage includes a second data voltage group supplying a second data voltage to a second sub-pixel group of the plurality of sub-pixels, respectively, where the second sub-pixel group is configured to emit light passing through the lens boundary portion, and where the second data voltage is different from the first data voltage.

According to various embodiments of the present disclosure, the first data voltage group may include the first data voltage supplied to the first sub-pixel group and the second data voltage supplied to the second sub-pixel group.

According to various embodiments of the present disclosure, the second data voltage group may include the second data voltage supplied to the second sub-pixel group.

According to various embodiments of the present disclosure, the second sub-pixel group includes a reference sub-pixel, and a third data voltage supplied to the reference sub-pixel in the first data voltage group may be different from a fourth data voltage input to the reference sub-pixel in the second data voltage group.

According to various embodiments of the present disclosure, the third data voltage supplied to the reference sub-pixel in the first data voltage group may be greater than the fourth data voltage supplied to the reference sub-pixel in the second data voltage group.

According to various embodiments of the present disclosure, the lens boundary portion may include a first lens boundary portion and a second lens boundary portion having a different width than a width of the first lens boundary portion.

According to various embodiments of the present disclosure, the number of sub-pixels disposed in the second sub-pixel group overlapping the first lens boundary portion may be different from the number of sub-pixels disposed in the second sub-pixel group overlapping the second lens boundary portion.

According to various embodiments of the present disclosure, the first data voltage group may include the first data voltage supplied to the first sub-pixel group and the second data voltage supplied to the second sub-pixel group overlapping the second lens boundary portion, and the second data voltage group may include the fourth data voltage supplied to the second sub-pixel group overlapping the first lens boundary portion.

According to various embodiments of the present disclosure, the second data voltage group may include the fourth data voltage supplied to the second sub-pixel group overlapping the first lens boundary portion and the fourth data voltage supplied to the second sub-pixel group overlapping the second lens boundary portion.

According to various embodiments of the present disclosure, the display device may further include a first base substrate disposed between the display panel and the lens assembly, and a second base substrate disposed on and spaced apart from the first base substrate. The lens assembly may be disposed between the first base substrate and the second base substrate.

According to various embodiments of the present disclosure, the display device may further include a filler layer disposed between the first base substrate and the second base substrate.

According to various embodiments of the present disclosure, the display device may further include a polarization control assembly disposed between the display panel and the lens assembly and including a driving liquid crystal configured to adjust a linear polarization direction of light emitted from the display panel.

According to various embodiments of the present disclosure, the display device may further include a third base substrate disposed between the display panel and the driving liquid crystal, and a fourth base substrate disposed between the driving liquid crystal and the first base substrate.

According to various embodiments of the present disclosure, the polarization control assembly may further include a first driving electrode disposed between the driving liquid crystal and the fourth base substrate, and a second driving electrode disposed between the third base substrate and the driving liquid crystal.

According to various embodiments of the present disclosure, the second sub-pixel group may be configured to receive the first data voltage group including the first data voltage to display a two-dimensional image, and the second sub-pixel group may be configured to receive the second data voltage group including a fourth data voltage to display a three-dimensional image.

According to various embodiments of the present disclosure, an electronic device includes a processor configured to provide an image signal, a display module configured to receive the an image signal and to display an image, and a power module configured to supply power to the display module. The display module includes a display driver configured to output an image data voltage, a display panel including a plurality of sub-pixels, and configured to receive the image data voltage and to emit light, and a lens assembly including a plurality of

lenses and a lens boundary portion disposed between the plurality of lenses, where the plurality of lenses is configured to refract the emitted light. The image data voltage includes a first data voltage group supplying a first data voltage to a first sub-pixel group of the plurality of sub-pixels, respectively, where the first sub-pixel group is configured to emit light passing through the plurality of lenses, and a second data voltage group supplying a second data voltage to a second sub-pixel group of the plurality of sub-pixels, respectively, where the second sub-pixel group is configured to emit light passing through the lens boundary portion, and where the second data voltage is different from the first data voltage.

According to various embodiments of the present disclosure, the first data voltage group may include the first data voltage supplied to the first sub-pixel group and the second data voltage supplied to the second sub-pixel group, and the second data voltage group may include the second data voltage supplied to the second sub-pixel group.

According to various embodiments of the present disclosure, the lens boundary portion may include a first lens boundary portion and a second lens boundary portion having a different width than a width of than the first lens boundary portion.

According to various embodiments of the present disclosure, the display module may further include a first base substrate disposed between the display panel and the lens assembly, and a second base substrate disposed on the first base substrate. The lens assembly may be disposed between the first base substrate and the second base substrate.

According to various embodiments of the present disclosure, the second sub-pixel group is configured to receive the first data voltage group including the first data voltage to display a two-dimensional image, and the second sub-pixel group is configured to receive the second data voltage group including a fourth data voltage to display a three-dimensional image.

The present disclosure may provide structures and configurations that prevent deterioration of display quality of a display device even though an error occurs in a manufacturing process of a light field display device. According to the present disclosure, deterioration of the display quality of a three-dimensional image can be prevented or reduced when refraction of light does not occur as designed on a surface where a lens and a filler layer are in contact with each other.

### BRIEF DESCRIPTION OF THE DRAWINGS

The above and other aspects and features of the present disclosure are apparent from the detailed description of the embodiments thereof with reference to the attached drawings, in which:

FIG. 1 is an exploded perspective view illustrating a display device according to an embodiment of the present disclosure;

FIG. 2 is a perspective view of the display device illustrated in FIG. 1;

FIG. 3 is a cross-sectional view illustrating a portion of the display device including emission areas;

FIG. 4 is a cross-sectional view illustrating an always-on light field display;

FIG. 5 is a cross-sectional view illustrating a first type of light field display configured to display a two-dimensional image;

FIG. 6 is a cross-sectional view illustrating the first type of light field display configured to display a three-dimensional image;

FIG. 7 is a cross-sectional view illustrating a second type of light field display configured to display a two-dimensional image;

FIG. 8 is a cross-sectional view illustrating the second type of light field display configured to display a three-dimensional image;

FIG. 9 is a plan view illustrating a filler layer and a lens including a normally formed boundary portion of the lens;

FIG. 10 is a cross-sectional view illustrating the filler layer and the lens including the normally formed boundary portion of the lens;

FIG. 11 is a plan view illustrating a filler layer and a lens including an abnormally formed boundary portion of the lens;

FIG. 12 is a cross-sectional illustrating the filler layer and the lens including the abnormally formed boundary portion of the lens;

FIG. 13 is a cross-sectional view illustrating a display device configured to display a three-dimensional image according to an embodiment of the present disclosure;

FIG. 14 is a cross-sectional view illustrating a display device configured to display a two-dimensional image according to an embodiment of the present disclosure;

FIG. 15 is a plan view illustrating an overlapping configuration between a sub-pixel group and a boundary portion of a lens according to an embodiment of the present disclosure;

FIG. 16 is a plan view illustrating a first data voltage group input to the sub-pixel group;

FIG. 17 is a plan view illustrating an area of a second sub-pixel group;

FIG. 18 is a plan view illustrating an area of a first sub-pixel group;

FIG. 19 is a plan view illustrating a second data voltage group is input to the area supplied to the second sub-pixel group according to an embodiment of the present disclosure;

FIG. 20 is a plan view illustrating an overlapping configuration between a sub-pixel group and a boundary portion of a lens according to an embodiment of the present disclosure;

FIG. 21 is a plan view illustrating a first data voltage group and a second data voltage group are input to the area corresponding to the second sub-pixel group according to an embodiment of the present disclosure;

FIG. 22 is a block diagram of an electronic device according to an embodiment of the present disclosure; and

FIG. 23 is schematic views of electronic devices according to various embodiments of the present disclosure.

### DETAILED DESCRIPTION OF THE EMBODIMENTS

Embodiments of the present disclosure are described with reference to the accompanying drawings. However, the inventive concept according to the present disclosure is not necessarily limited to the embodiments disclosed herein, but may be embodied in many different forms, and these embodiments are provided merely to make the disclosure complete and to fully inform one of ordinary skill in the art to which the invention according to the present disclosure belongs.

References to an element or layer as being “on” another element or layer include both cases in which another layer or element is directly on top of or interposed between other elements. The same reference numerals may be used to indicate the same elements disclosure and the drawings. For example, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Although the terms “first,” “second,” and the like are used to describe various components, the components are not necessarily limited by these terms. Thus, a first component referred to herein may also be a second component within the technical idea of the present invention.

Each of the features of the various embodiments disclosed herein may be combined or combinable with each other, in part or in whole, and may be technically interlocked and operated in a variety of ways, and each embodiment may be practiced independently of or in conjunction with one another.

Specific embodiments are described below with reference to the accompanying drawings. Configurations that function substantially the same between embodiments are given the same drawing designation and the difference between the embodiments may be described.

Embodiments of the present disclosure provide a display device including a display panel and an optical member in which a plurality of lenses is formed between a first base substrate and a second base substrate. The display panel includes a plurality of sub-pixels arranged into sub-pixel groups, where first sub-pixel groups are aligned with normal boundary portions of the lenses and second sub-pixel groups are aligned with abnormal boundary portions of the lenses. To prevent deterioration of three-dimensional image quality caused by light leakage or refraction at the abnormal boundary portions, the display device applies different data voltage groups to the first and second sub-pixel groups.

For example, a first data voltage group is supplied to the first sub-pixel groups to maintain normal luminance, and a second data voltage group having reduced voltage values is supplied to the second sub-pixel groups to suppress light output. Accordingly, the display device maintains accurate color balance, resolution, and stereoscopic image quality even when lens boundary portions are abnormally formed during the manufacturing process.

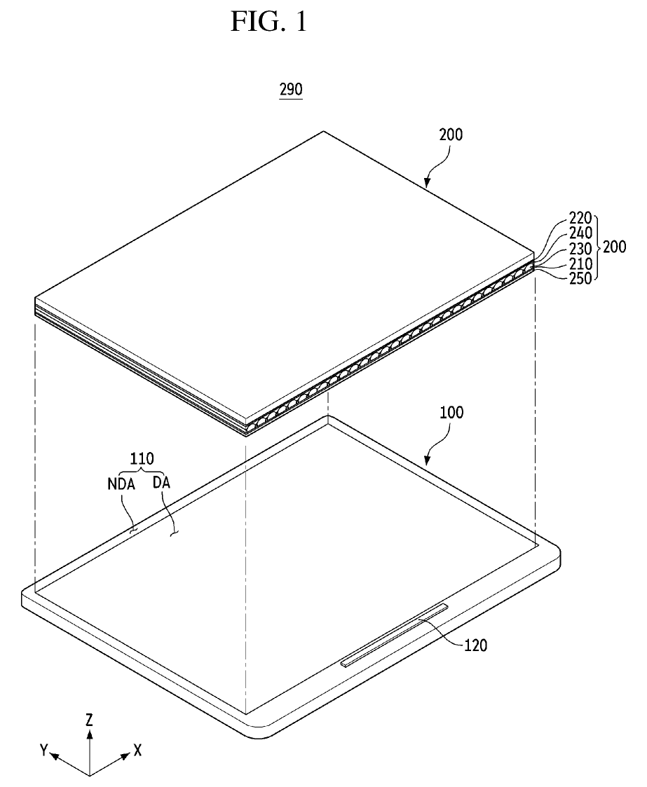

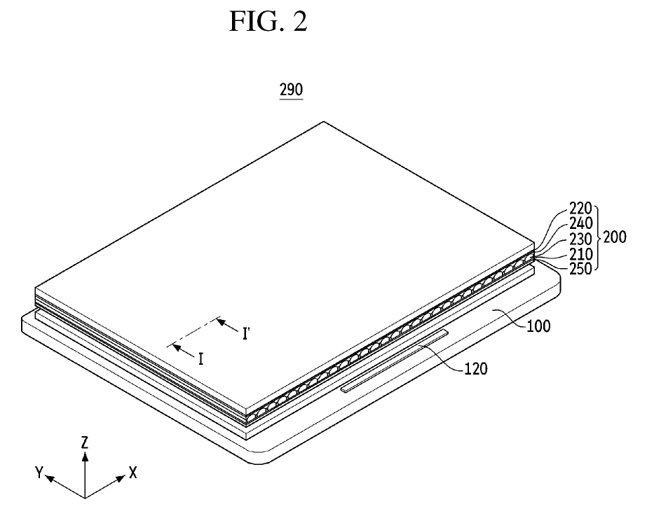

FIG. 1 is an exploded perspective view illustrating a display device according to an embodiment of the present disclosure. FIG. 2 is a perspective view of the display device illustrated in FIG. 1.

A display device 290 may be implemented as a flat panel display device such as a liquid crystal display (LCD), a field emission display (FED), a plasma display panel (PDP), and an organic light emitting display (OLED). In some embodiments, the display device 290 may be implemented as a micro-light emitting diode (micro-LED) display, a quantum-dot light emitting diode (QLED) display, or other emissive and non-emissive display devices.

In one aspect, the display device 290 may be a stereoscopic image display device, a three-dimensional (3D) image display device, including a display module 100 and an optical member 200. To display a 3D image, the stereoscopic image display device may separate and display a left-eye image and a right-eye image in a forward viewing direction such that a three-dimensional effect is perceived using based on binocular parallax. Furthermore, the stereoscopic image display device may separate and provide a plurality of viewing angle images toward the forward viewing direction such that different images are perceived at different viewing angles, thereby supporting multi-view image reproduction.

The display device 290 may be a light field display that enables different image information to be viewed by both eyes of the viewer by including the optical member 200 disposed on a front surface of the display module 100. The light field display may form a light field and generate a 3D stereoscopic image by using the display module 100 configured to display a two-dimensional (2D) image and the optical member 200 configured to convert the 2D image into a 3D image and displaying the 3D image. The light field display enables image display light generated from each pixel of the display module 100 to form a light field directed in a specific direction (a specific viewing angle and/or a specific point of view) by a stereoscopic lens, a pinhole, a barrier, or the like, included in the optical member 200. Accordingly, 3D stereoscopic image information corresponding to the specific direction may be provided toward the viewing position of the viewer.

The display module 100 may include a display panel 110 and a display driver 120. In some embodiments, the display module 100 may further include a timing controller, a power storage circuit, or other auxiliary circuits electrically coupled to the display driver 120.

The display panel 110 may include a display area DA and a non-display area NDA. The display area DA may include data lines, scan lines, voltage supply lines, and a plurality of pixels connected to the corresponding data lines and scan lines. For example, the scan lines may extend in a first direction (e.g., an X-axis direction) and may be spaced apart from each other in a second direction (e.g., a Y-axis direction). The data lines and the voltage supply lines may extend in the second direction (e.g., the Y-axis direction) and may be spaced apart from each other in the first direction (e.g., the X-axis direction). In some embodiments, the non-display area NDA may include peripheral circuits such as gate drivers, data drivers, or bonding pads for electrical connection to an external circuit board.

Each pixel (or unit pixel) formed and arranged in the display panel 110 includes a minimum number of sub-pixels capable of emitting white light. For example, each pixel may include three sub-pixels respectively emitting red light, green light, and blue light. Each of the sub-pixels is alternately arranged and electrically connected to at least one scan line, data line, and power supply line. Each of the sub-pixels may include thin film transistors including a driving transistor and at least one switching transistor, a light emitting element, and a capacitor. Each of the pixels may receive a data voltage of the data line when a scan signal is applied from the scan line to each of the pixels, and may emit light by supplying a driving current to the light emitting element according to the data voltage applied to a gate electrode of the driving transistor. In some embodiments, each pixel may further include four sub-pixels each emitting red light, green light, blue light, and white light to improve luminance efficiency.

In an embodiment, the pixels (e.g., the respective unit pixels) of the display panel 110 display a two-dimensional multi-view image based on image data generated by the display driver 120. The multi-view image includes n view images (for example, n is a natural number greater than or equal to 2). For example, the n view images are images generated by capturing an image of a specific object (or content) with n cameras spaced apart from each other using a binocular distance of an ordinary person.

For example, the n view images may include first data by collecting the specific content from a first viewing angle, second data by collecting the specific content from a second viewing angle, …, and n-th data by collecting the specific content from an n-th viewing angle. A plurality of data (first data to n-th data) may be digital data. In some embodiments, the plurality of view images may be generated synthetically using computer graphics rendering techniques or machine learning-based interpolation methods, instead of direct capture by physical cameras. In some embodiments, the binocular distance between the cameras may be adjustable or non-uniform to optimize depth perception for particular display or viewing conditions.

The display panel 110 may display the multi-view image in units of n pixels during an image display period. For example, the display panel 110 may display the multi-view image in units of two pixels. For example, two pixels of the display panel 110 may display the multi-view image including two view images. In particular, the display panel 110 may display the multi-view image in units of time-division frame (or sub-frame) periods based on the time-division driving of the display driver 120. For example, the display panel 110 may display the multi-view image in units of two pixels for each time-division frame period. The time-division frame period is a period in which one frame period is divided and driven in units of 1/2 or 1/3 frame periods. In some embodiments, the time-division frame period may be further divided into 1/4 or smaller sub-frame periods to increase the number of supported viewing angles.

The non-display area NDA may surround the display area DA at an edge of the display panel 110. The non-display area NDA may include a scan driver applying scan signals to the scan lines and pads connected to the display driver 120. For example, the display driver 120 may be disposed on one side of the non-display area NDA, and the pads may be disposed at an edge of one side of the non-display area NDA on which the display driver 120 is disposed.

The display driver 120 may output control signals and image data voltages for driving the display panel 110 in units of at least one frame or units of at least one time-division frame (subframe). For example, the display driver 120 may supply image data voltages to the data lines in units of at least one time-division frame (subframe). The display driver 120 may supply a source voltage to the power supply line and supply scan control signals to the scan driver. The image data voltage may include a plurality of data voltages supplied to a plurality of pixels (or sub-pixels) connected to a plurality of data lines. In some embodiments, the display driver 120 may reduce power consumption by using variable refresh rate or low frame-rate driving modes.

The optical member 200 includes an lens assembly 230 (e.g., a refractive index anisotropic lens) formed between first and second base substrates 210 and 220, a polarization control assembly 250 formed to overlap the lens assembly 230, and a filler layer 240 disposed between the lens assembly 230 and the second base substrate 220. For example, the optical member 200 may include the first base substrate 210, the lens assembly 230, the filler layer 240, and the second base substrate 220 sequentially stacked.

The display driver 120 may be formed as an integrated circuit (IC) and disposed in the non-display area NDA of the display panel 110 in a chip on glass (COG) manner, a chip on plastic (COP) manner, or an ultrasonic bonding manner. As an example, the display driver 120 may be mounted on a circuit board and connected to the pads of the display panel 110.

The optical member 200 may be disposed in a forward viewing direction of the display panel 110 or the display module 100. The optical member 200 may be attached to one surface of the display panel 110 or the display area DA through an adhesive member. For example, an optical member 200 may be laminated with the front surface of the display module 100 using a separate panel lamination device.

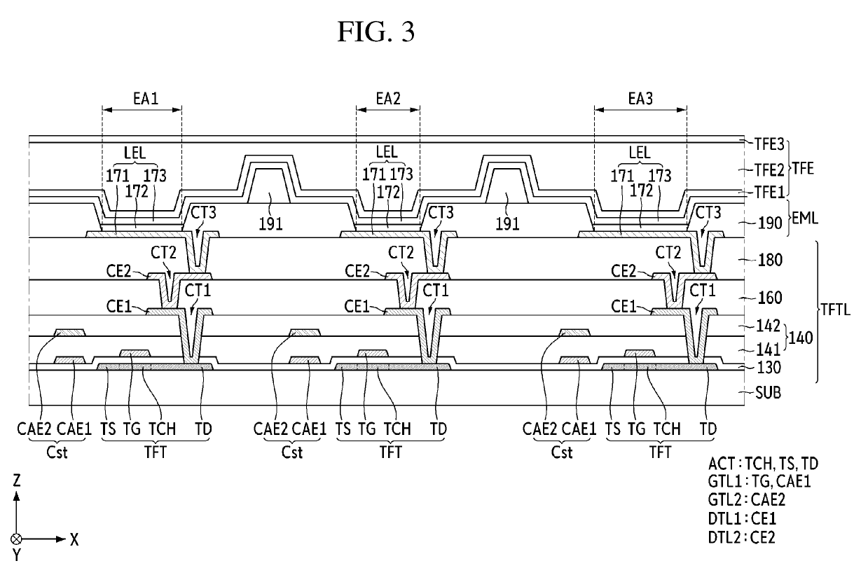

FIG. 3 is a cross-sectional view illustrating a portion of the display device including emission areas.

Referring to FIG. 3, the display panel 110 may include a substrate SUB, a thin film transistor layer TFTL, a light emitting element layer EML, and an encapsulation film TFE. The substrate SUB may be a glass substrate or a flexible polymer substrate configured to support overlying device layers. The thin film transistor layer TFTL may be formed on an upper surface of the substrate SUB, and the light emitting element layer EML may be sequentially stacked above the thin film transistor layer TFTL. The encapsulation film TFE may be disposed to cover the light emitting element layer EML and protect the light emitting element layer EML from oxygen and moisture.

The thin film transistor layer TFTL may include an active layer ACT, a first gate metal layer GTL1, a second gate metal layer GTL2, a first data metal layer DTL1, and a second data metal layer DTL2. In addition, the thin film transistor layer TFTL may include a buffer layer, a gate insulating film 130, a first interlayer insulating film 141, a second interlayer insulating film 142, a first planarization film 160, and a second planarization film 180. The thin film transistor layer TFTL includes a plurality of thin film transistors TFT, and each of the plurality of thin film transistors TFT may include a channel TCH, a gate electrode TG, a first electrode TS, and a second electrode TD.

The active layer ACT may be disposed on the substrate SUB. The active layer ACT may include a silicon semiconductor such as polycrystalline silicon, single crystal silicon, and low-temperature polycrystalline silicon. In some cases, the active layer ACT may include an oxide semiconductor.

For each of the plurality of thin film transistors TFT, the active layer ACT may include the channel TCH, the first electrode TS, and the second electrode TD. The channel TCH may be a region overlapping the gate electrode TG of the thin film transistor TFT in a third direction (e.g., a Z-axis direction), which corresponds to a thickness direction of the substrate SUB. The first electrode TS may be disposed on one side of the channel TCH, and the second electrode TD may be disposed on the other side of the channel TCH. The first electrode TS and the second electrode TD are positioned such that the first electrode TS and the second electrode TD do not overlap the gate electrode TG in the third direction (e.g., the Z-axis direction). The first electrode TS and the second electrode TD are formed as doped regions of the semiconductor layer, where the doping ions impart conductivity to the silicon or oxide semiconductor material.

The gate insulating film 130 may be disposed on the active layer ACT. The gate insulating film 130 may be formed as an inorganic film such as a silicon nitride layer, a silicon oxynitride layer, a silicon oxide layer, a titanium oxide layer, or an aluminum oxide layer. In some embodiments, the gate insulating film 130 may include a multi-layer stack of two or more inorganic films. In some embodiments, the gate insulating film 130 may further include an organic-inorganic dielectric layer.

The first gate metal layer GTL1 may be disposed on the gate insulating film 130. The first gate metal layer GTL1 may include the gate electrode TG for each of the plurality of thin film transistors TFT and a first capacitor electrode CAE1. The first gate metal layer GTL1 may be formed as a single layer or multiple layers including at least one of molybdenum (Mo), aluminum (Al), chromium (Cr), gold (Au), titanium (Ti), nickel (Ni), neodymium (Nd), and copper (Cu), or alloys thereof.

The first interlayer insulating film 141 may be disposed on the first gate metal layer GTL1. The first interlayer insulating film 141 may be formed as an inorganic film such as a silicon nitride layer, a silicon oxynitride layer, a silicon oxide layer, a titanium oxide layer, or an aluminum oxide layer. In some embodiments, the first interlayer insulating film 141 may be a multi-layer dielectric stack including alternating nitride and oxide films. In some cases, the first interlayer insulating film 141 may serve as a planarization layer.

The second gate metal layer GTL2 may be disposed on the first interlayer insulating film 141. The second gate metal layer GTL2 may include a second capacitor electrode CAE2. The second capacitor electrode CAE2 may overlap the first capacitor electrode CAE1 in the third direction (e.g., the Z-axis direction). A capacitor Cst may include the first capacitor electrode CAE1 and the second capacitor electrode CAE2. The second gate metal layer GTL2 may be formed as a single layer or multiple layers including at least one of molybdenum (Mo), aluminum (Al), chromium (Cr), gold (Au), titanium (Ti), nickel (Ni), neodymium (Nd), and copper (Cu), or alloys thereof.

The second interlayer insulating film 142 may be disposed on the second gate metal layer GTL2. The second interlayer insulating film 142 may be formed as an inorganic film such as a silicon nitride layer, a silicon oxynitride layer, a silicon oxide layer, a titanium oxide layer, or an aluminum oxide layer. In some embodiments, the second interlayer insulating film 142 may be a multilayer stack including alternating nitride and oxide layers to enhance barrier characteristics and reduce leakage current.

The first data metal layer DTL1 including a first connection electrode CE1 may be disposed on the second interlayer insulating film 142. The first connection electrode CE1 may be connected to the first electrode TS or the second electrode TD of the thin film transistor TFT through a first contact hole CT1 penetrating through the gate insulating film 130, the first interlayer insulating film 141, and the second interlayer insulating film 142. The first data metal layer DTL1 may be formed as a single layer or multiple layers including at least one of molybdenum (Mo), aluminum (Al), chromium (Cr), gold (Au), titanium (Ti), nickel (Ni), neodymium (Nd), and copper (Cu), or alloys thereof.

The first planarization film 160 may be disposed on the first data metal layer DTL1. For example, the first planarization film 160 may serve as a planarization layer so that an upper surface of the first planarization film 160 disposed on the active layer ACT, the first gate metal layer GTL1, the second gate metal layer GTL2, and the first data metal layer DTL1 is substantially flat. The first planarization film 160 may be formed as an organic film made of an acrylic resin, an epoxy resin, a phenolic resin, a polyamide resin, a polyimide resin, or other resins. In some embodiments, the first planarization film 160 may further include a filler material to improve surface leveling.

The second data metal layer DTL2 may be disposed on the first planarization film 160. The second data metal layer DTL2 may include a second connection electrode CE2. The second connection electrode CE2 may be connected to the first connection electrode CE1 through a second contact hole CT2 penetrating through the first planarization film 160. The second data metal layer DTL2 may be formed as a single layer or multiple layers including at least one of molybdenum (Mo), aluminum (Al), chromium (Cr), gold (Au), titanium (Ti), nickel (Ni), neodymium (Nd), and copper (Cu), or alloys thereof. In some embodiments, the second data metal layer DTL2 may further include a barrier metal layer such as titanium nitride (TiN) or tantalum nitride (TaN).

The second planarization film 180 may be disposed on the second data metal layer DTL2. The second planarization film 180 may be formed as an organic film made of an acrylic resin, an epoxy resin, a phenolic resin, a polyamide resin, a polyimide resin, or other resins. In some cases, for example, the second planarization film 180 may cover the second data metal layer DTL2 and the first planarization film 160.

The light emitting element layer EML may be disposed on the second planarization film 180. The light emitting element layer EML may include a plurality of light emitting elements LEL and a pixel defining film 190. Each of the plurality of light emitting elements LEL may be an organic light emitting diode element including a pixel electrode 171, a light emitting layer 172, and a common electrode 173, but an embodiment of the present disclosure is not necessarily limited thereto. For example, the light emitting element layer EML may include inorganic micro-light emitting diode (micro-LED) elements or quantum-dot structures.

The pixel electrode 171 may be disposed on the second planarization film 180. The pixel electrode 171 may be connected to the second connection electrode CE2 through a third connection hole CT3 penetrating through the second planarization film 180.

In a top emission structure (or an upper portion of the light emitting layer 172) in which light is emitted toward the common electrode 173 through the light emitting layer 172, the pixel electrode 171 may include a metal material having high reflectivity, such as a stacked structure (Ti/Al/Ti) of aluminum and titanium, a stacked structure (ITO/Al/ITO) of aluminum and indium tin oxide (ITO), an APC alloy, and a stacked structure (ITO/APC/ITO) of an APC alloy and ITO. The APC alloy is an alloy including silver (Ag), palladium (Pd), and copper (Cu).

The pixel defining film 190 may cover an edge of each of the pixel electrodes 171 on the second planarization film 180 in order to define a plurality of emission areas EA1, EA2, and EA3. The pixel defining film 190 may be formed as an organic film made of an acrylic resin, an epoxy resin, a phenolic resin, a polyamide resin, a polyimide resin, or other resins. In some embodiments, the pixel defining film 190 may include black resin materials to reduce optical crosstalk between adjacent sub-pixels. By surrounding the edges of the pixel electrodes 171 and defining the emission areas EA1, EA2, and EA3, the pixel defining film 190 may reduce electrical and optical crosstalk between adjacent sub-pixels, enhance emission uniformity, and enable higher resolution in stereoscopic multi-view image reproduction.

Each of the plurality of emission areas EA1, EA2, and EA3 refers to an area where the pixel electrode 171, the light emitting layer 172, and the common electrode 173 are sequentially stacked. Additionally, each of the plurality of emission areas EA1, EA2, and EA3 may include holes from the pixel electrode 171 and electrons from the common electrode 173 in the light emitting layer 172 that emit light. In some embodiments, the emission areas EA1, EA2, and EA3 may correspond to red, green, and blue sub-pixels, respectively. In other embodiments, one or more of the emission areas may correspond to a white or yellow sub-pixel.

The light emitting layer 172 may be disposed on the pixel electrode 171. The light emitting layer 172 may include an organic material configured to emit light having a selected color. For example, the light emitting layer 172 may include a hole transporting layer, an organic material layer, and an electron transporting layer.

The common electrode 173 may be disposed on the light emitting layer 172. The common electrode 173 may cover the light emitting layer 172. The common electrode 173 may be a common layer formed in common in the plurality of emission areas EA1, EA2, and EA3. A capping layer may be formed on the common electrode 173. In some embodiments, the capping layer may be a transparent inorganic oxide layer or an organic protective layer.

An upper region or upper surface of the common electrode 173 may include a transparent conductive material (TCO) such as ITO or indium zinc oxide (IZO) capable of transmitting light or a semi-transmissive conductive material such as magnesium (Mg), silver (Ag), or an alloy of magnesium (Mg) and silver (Ag). When the common electrode 173 includes the semi-transmissive conductive material, light emission efficiency may be increased by an optical micro cavity. In some embodiments, the common electrode 173 may further include multilayer dielectric structures.

A spacer 191 may be disposed on the pixel defining film 190. The spacer 191 may serve to support a mask during a process of manufacturing the light emitting layer 172. The spacer 191 may be formed as an organic film made of an acrylic resin, an epoxy resin, a phenolic resin, a polyamide resin, a polyimide resin, or other resins. In some embodiments, the spacer 191 may be formed as an inorganic film.

The encapsulation film TFE may be disposed on the common electrode 173. The encapsulation film TFE may include at least one inorganic film, which prevents oxygen or moisture from permeating into the light emitting element layer EML. In addition, the encapsulation film TFE may include at least one organic film that protects the light emitting element layer EML from foreign substances such as dust. For example, the encapsulation film TFE may include a first encapsulation inorganic film TFE1, an encapsulation organic film TFE2, and a second encapsulation inorganic film TFE3. In some embodiments, the encapsulation film TFE may be implemented as a multi-layer stacked structure having alternating inorganic and organic layers.

The first encapsulation inorganic film TFE1 may be disposed on the common electrode 173, the encapsulation organic film TFE2 may be disposed on the first encapsulation inorganic film TFE1, and the second encapsulation inorganic film TFE3 may be disposed on the encapsulation organic film TFE2. Each of the first encapsulation inorganic film TFE1 and the second encapsulation inorganic film TFE3 may be formed as multiple films in which one or more inorganic films of a silicon nitride layer, a silicon oxynitride layer, a silicon oxide layer, a titanium oxide layer, and an aluminum oxide layer are alternately stacked. The encapsulation organic film TFE2 may be an organic film made of an acrylic resin, an epoxy resin, a phenolic resin, a polyamide resin, a polyimide resin, or other resins.

As illustrated in FIG. 3, for example, the width of a third emission area EA3 is greater than the width of a first emission area EA1, and the width of the first emission area EA1 is greater than the width of a second emission area EA2. For example, the first emission area EA1 may be a red emission area, the second emission area EA2 may be a green emission area, and the third emission area EA3 may be a blue emission area. However, an embodiment of the present disclosure is not necessarily limited to relative sizes of the emission areas. For example, the relative sizes of the emission areas EA1, EA2, and EA3 may be varied based on a target color balance or application requirements.

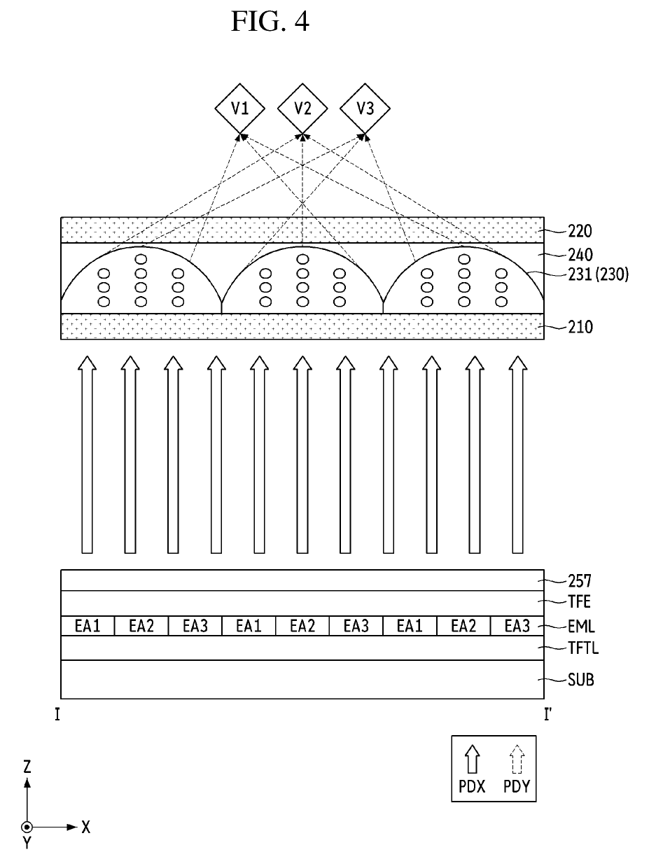

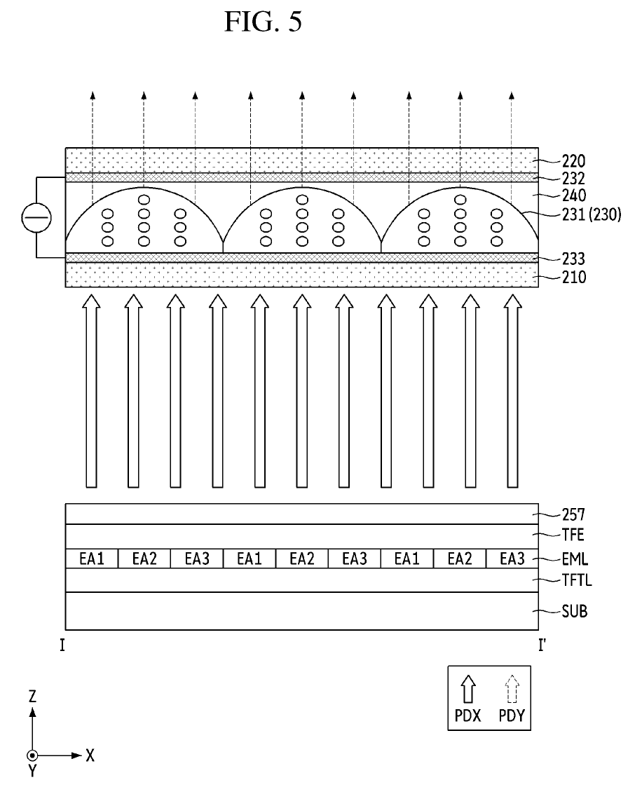

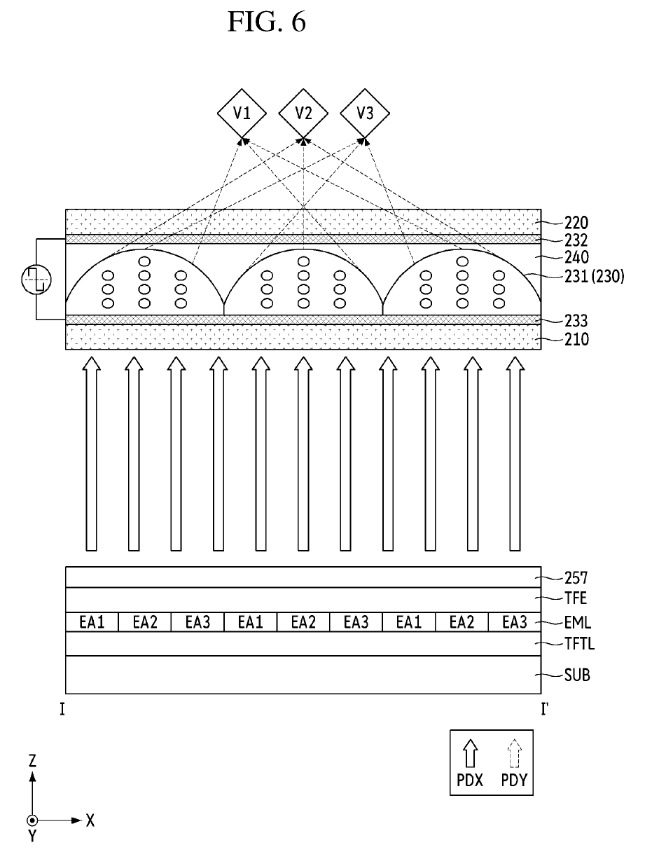

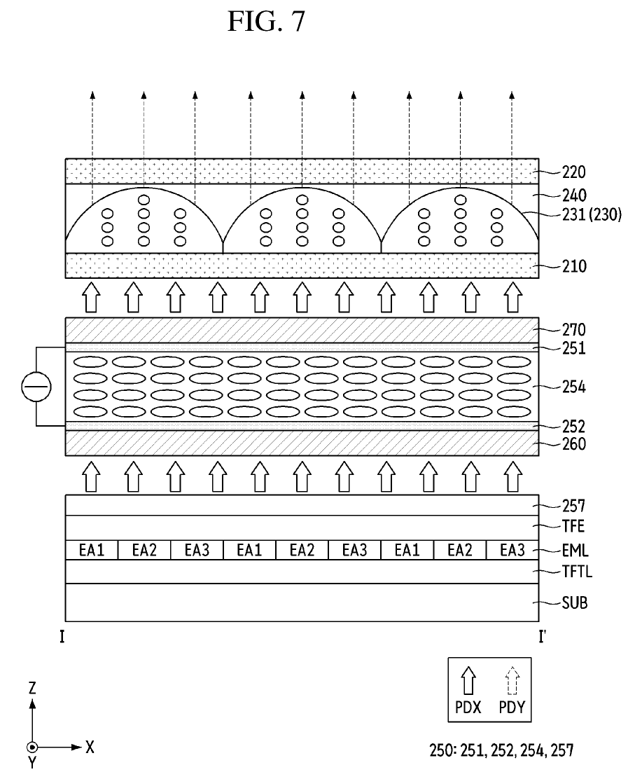

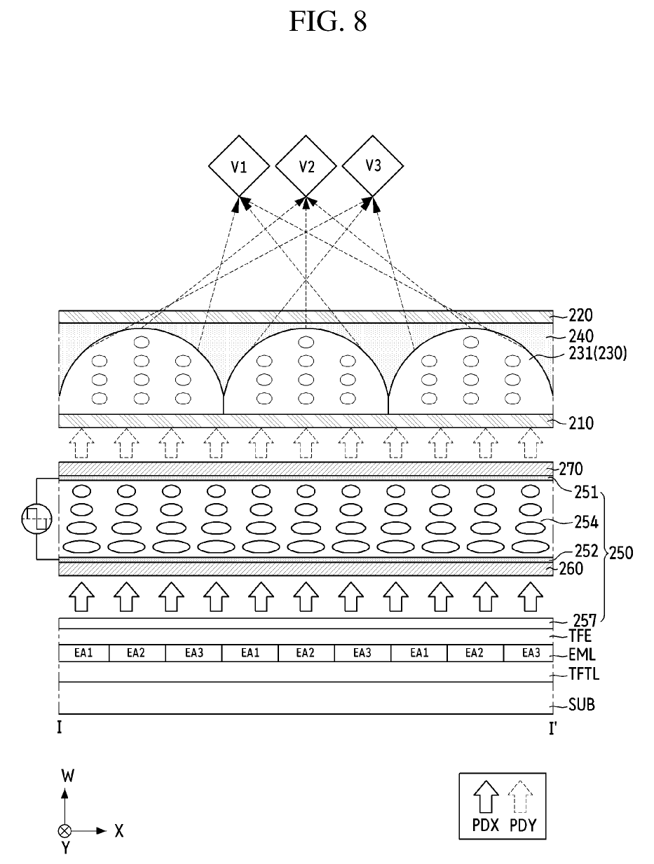

FIG. 4 is a cross-sectional view illustrating an always-on light field display. FIG. 5 is a cross-sectional view illustrating a first type of light field display configured to display a two-dimensional image. FIG. 6 is a cross-sectional view illustrating the first type of light field display configured to display a three-dimensional image. FIG. 7 is a cross-sectional view illustrating a second type of light field display configured to display a two-dimensional image. FIG. 8 is a cross-sectional view illustrating the second type of light field display configured to display a three-dimensional image.

The light field display may allow different image information to be viewed by both eyes of the viewer by including the optical member disposed on the front surface of the display module, as described above. The light field display may be configured to display a two-dimensional image or a three-dimensional image. In some embodiments, the light field display may dynamically switch between the two-dimensional image mode and the three-dimensional image mode based on control signals supplied to the optical member.

A specific content may include not only real-world content, such as texts, pictures, things, and objects, but also digital or virtual content generated computationally and does not exist in the real world. First data may be derived by collecting the specific content from a first viewing angle. Second data may be derived by collecting the specific content from a second viewing angle. Furthermore, n-th data may be derived when the specific content is collected from an n-th viewing angle. In some embodiments, the multi-angle content may be generated using a plurality of physical cameras arranged with predetermined spacing, or using computer graphics rendering or machine learning-based view synthesis.

According to an embodiment, the display device may include a display panel in which a plurality of light emitting elements are disposed and an optical member disposed on the display panel. Light emitted from each light emitting element disposed in the display panel may be refracted while passing through the optical member based on whether or not a 3D image is to be displayed. For example, when the 3D image is to be displayed, the light emitted from any light emitting element may be refracted in the optical member. For example, when a 2D image is to be displayed, the light emitted from any light emitting element might not be refracted in the optical member.

However, even when the 2D image is to be displayed, the light emitted from the corresponding light emitting element may be refracted, and for example, a resolution deterioration problem of the display device may occur.

A viewing angle may be assigned to each of the plurality of light emitting elements by adjusting refraction directions of light emitted from the plurality of light emitting elements. This may be referred to as viewing angle mapping. In order to adjust the directions of the light emitted from the light emitting elements, a pitch, a tilt angle, and other parameters, of lenses (e.g., slanted lenses) included in the optical member may be adjusted.

A specific viewing angle may be mapped to each of the plurality of light emitting elements, and light emitted from the light emitting element to which the specific viewing angle is mapped may travel in a direction of the assigned viewing angle. For example, light emitted from a light emitting element to which the first viewing angle is mapped may travel in a direction of the first viewing angle where a first view area is disposed, and light emitted from a light emitting element to which the second viewing angle is mapped may travel in a direction of the second viewing angle where a second view area is disposed. In some embodiments, a plurality of additional viewing angles may be mapped to generate multiple view areas.

The first data derived by collecting the specific content from the first viewing angle may be input to the light emitting element to which the first viewing angle is mapped. The second data may be input to the light emitting element to which the second viewing angle is mapped. In some embodiments, data corresponding to a plurality of view angles may be simultaneously or sequentially provided to the corresponding light emitting elements.

The first viewing angle may be disposed on one side (e.g., the left eye side) from the center of both eyes of a viewer. The second viewing angle may be disposed on the other side (e.g., the right eye side) from the center of both eyes of the viewer.

When different images are perceived by the viewer’s left and right eyes regardless of which viewing angle is mapped, the viewer may feel that a three-dimensional image is displayed from the display device. When the same image is perceived by the viewer’s left and right eyes, the viewer may perceive a two-dimensional image from the display device. For example, when the same image is perceived by the viewer’s left and right eyes, light emitted from the display panel might not be refracted. However, as described above, even though the light emitted from the display panel is refracted, the same image may be perceived by the viewer’s left and right eyes, and for example, a resolution deterioration problem of the display device may occur. Thus, controlling the refraction of light emitted from the display device may enhance the resolution of the images.

Accordingly, the viewer may perceive a three-dimensional image when the first data is input to the light emitting element corresponding to the first viewing angle and the second data is input to the light emitting element corresponding to the second viewing angle.

Alternatively, the viewer may perceive a two-dimensional image when the first data is input to both the light emitting element corresponding to the first viewing angle and the light emitting element corresponding to the second viewing angle. The light emitted from the light emitting element corresponding to the first viewing angle may be refracted even when the two-dimensional image is displayed, and the light emitted from the light emitting element corresponding to the second viewing angle may be refracted.

Alternatively, the two-dimensional image may be displayed when the light emitted from the light emitting element might not be refracted in the optical member. For example, any light emitted from the light emitting element is not refracted regardless of the viewing angle is mapped to the light emitting element, and thus, the viewer may perceive the two-dimensional image. A resolution of the two-dimensional image displayed as described above may be relatively greater than a resolution of the two-dimensional image displayed when the light is refracted and the same image can be perceived by the viewer’s both eyes.

For example, the two-dimensional image may be displayed when the light emitted from the light emitting element is not refracted in the optical member or when the same data is input to light emitting elements even though the light emitted from the light emitting element is refracted in the optical member. In addition, resolutions of the two-dimensional images in each case may be different from each other.

The light field display may include a switchable display device configured to determine whether to display the two-dimensional image or the three-dimensional image by adjusting whether the light emitted from the display panel is refracted. The light field display may include a non-switchable display device (or an always-on light field display) in which the light emitted from the display panel is always refracted. When the non-switchable display device refract the light emitted from the display panel, the two-dimensional image may be displayed when the same data is input to the light emitting elements regardless of the viewing angle. When the two-dimensional image is displayed in the non-switchable display device, a resolution deterioration problem may occur.

The switchable display device may determine whether to display the two-dimensional image or the three-dimensional image by adjusting a linear polarization direction of the light emitted from the display panel and utilizing refractive index anisotropy of lenses included in the lens assembly.

For example, the light emitted from the display panel may pass through a polarizing member disposed above the display panel and pass along in a first linear polarization direction.

In an embodiment, a minor axis direction of the lens included in the lens assembly may coincide with the first linear polarization direction. A major axis direction of the lens may coincide with a second linear polarization direction.

The lens assembly may further include a filler layer disposed on a plurality of lenses. The plurality of lenses may have birefringence characteristics. For example, a refractive index of the lens in the minor axis direction may be the same as a refractive index of the filler layer, and a refractive index of the lens in the major axis direction may be greater than the refractive index of the filler layer. However, embodiments of the present disclosure are not necessarily limited thereto.

For example, when a voltage is not applied to the lens, the minor axis direction of the lens may be parallel to the path in the first linear polarization direction. When the light having the path in the first linear polarization direction and emitted from the display panel passes through the lens, the light may experience the refractive index of the lens in the minor axis direction coinciding with the first linear polarization direction. Since the refractive index of the lens in the minor axis direction is the same as the refractive index of the filler layer, the light passing through the lens may travel straight without being refracted at an interface between the lens and the filler layer. For example, since the light is not refracted, light perceived by both eyes of the viewer may be the straight traveling light, and the viewer may perceive a two-dimensional image. Such a mechanism may be applied to the first type of light field display in which the two-dimensional image is displayed (see FIG. 5).

For example, when a voltage is applied to the lens, the major axis direction of the lens may be parallel to the path in the first linear polarization direction. When the light having the path in the first linear polarization direction and emitted from the display panel passes through the lens, the light may experience the refractive index of the lens in the major axis direction coinciding with the first linear polarization direction. Since the refractive index of the lens in the major axis direction is greater than the refractive index of the filler layer, the light passing through the lens may be refracted at the interface between the lens and the filler layer. For example, since the light is refracted, light perceived by both eyes of the viewer may be the refracted light, and the viewer may feel perceive a three-dimensional image. Such a mechanism may be applied to the first type of light field display in which the three-dimensional image is displayed (see FIG. 6). Accordingly, this operating mode enables stereoscopic generation by directing different image information toward different viewing angles towards the viewer.

In the second type of light field display, a voltage might not be applied to the lens, and the minor axis direction and the major axis direction of the lens may be fixed and parallel to the first linear polarization direction and the second linear polarization direction, respectively (see FIGS. 7 and 8). Instead, the light having the path in the first linear polarization direction and emitted from the display panel may pass through a separate driving liquid crystal disposed between driving electrodes. Light passing through the driving liquid crystal, where a voltage is not applied, may pass through the driving liquid crystal while being maintained at the path in the first linear polarization direction (see FIG. 7). Light passing through the driving liquid crystal, where a voltage is applied, may pass through the driving liquid crystal while being switched from the path in the first linear polarization direction to a path in the second linear polarization direction (see FIG. 8).

Since the minor axis direction and the major axis direction of the lens are parallel to the first linear polarization direction and the second linear polarization direction, respectively, when the light passing through the driving liquid crystal has the path in the first linear polarization direction, the light may experience the refractive index of the lens in the minor axis direction. When the light passing through the driving liquid crystal has the path in the second linear polarization direction, the light may experience the refractive index of the lens in the major axis direction. Since the refractive index of the lens in the minor axis direction is the same as the refractive index of the filler layer and the refractive index of the lens in the major axis direction is greater than the refractive index of the filler layer, the refraction of the light passing through the driving liquid crystal can be determined at the interface between the lens and the filler layer based on the linear polarization direction of the light passing through the driving liquid crystal. Accordingly, the second type of light field display enables switching between two-dimensional and three-dimensional modes by controlling polarization direction within the driving liquid crystal.

As described above, the switchable light field display may include the first type of light field display (see FIGS. 5 and 6) and the second type of light field display (see FIGS. 7 and 8). These two types of light field displays provide alternative mechanisms for switching between two-dimensional and three-dimensional display modes.

In the first type of light field display, as described above, the linear polarization direction of the light passing through the display panel is not changed. Instead, the first type of light field display may directly change the major axis direction and the minor axis direction of the lens having the birefringence characteristics. Any changed axis direction coincides with the linear polarization direction of the light passing through the display panel, and the light may pass through the interface while experiencing the refractive index of the lens in the corresponding changed axis direction. Accordingly, the first type enables polarization-independent switching by electrically controlling the orientation of the birefringent lens.

In the second type of light field display, the light passing through the display panel may have the linear polarization direction changed while passing through the driving liquid crystal. In some cases, the second type of light field display might not directly change the major axis direction and the minor axis direction of the lens having the birefringence characteristics. Accordingly, the linear polarization direction of the light passing through the driving liquid crystal coincides with a fixed axis direction of the lens, and the light may pass through the interface while experiencing a corresponding refractive index of the lens in the fixed axis direction.

Referring to FIGS. 7 and 8, in the second type of light field display, the display panel may include a substrate SUB, a thin film transistor layer TFTL, a light emitting element layer EML, and an encapsulation film TFE. These structural elements correspond to the elements described with respect to FIG. 3.

The substrate SUB may have rigidity to support an element formed on the substrate SUB. For example, the substrate SUB may be a glass substrate or a plastic substrate such as a polyethylene terephthalate (PET) substrate. In some embodiments, the substrate SUB may be a flexible polymer substrate.

The thin film transistor layer TFTL may be disposed on the substrate SUB. The thin film transistor layer TFTL may adjust brightness of the display device 290. The thin film transistor layer TFTL may include transistors. In some cases, the thin film transistor layer TFTL may include capacitor elements configured to stabilize voltage applied to the light emitting elements.

The light emitting element layer EML may be disposed on the thin film transistor layer TFTL. The light emitting element layer EML may include first, second, and third emission areas EA1, EA2, and EA3. The first, second, and third emission areas EA1, EA2, and EA3 may be alternately disposed. In some embodiments, the emission areas EA1, EA2, and EA3 may correspond to red, green, and blue sub-pixels, respectively. In some cases, the display device may include an additional emission area configured to emit white light.

The encapsulation film TFE may be disposed on the light emitting element layer EML. The encapsulation film TFE may include at least one inorganic film and at least one organic film for encapsulating the light emitting element layer. For example, the encapsulation film TFE may include a multilayer stacked structure configured to prevent penetration of oxygen and moisture.

The optical member may include an lens assembly 230 disposed between a first base substrate 210 and a second base substrate 220. The lens assembly 230 may include a plurality of lenses 231. The optical member may include a filler layer 240 disposed between the first base substrate 210 and the second base substrate 220. For example, FIGS. 7 and 8 illustrate that the filler layer 240 is disposed on the lens assembly 230, but an embodiment of the present disclosure is not necessarily limited thereto. For example, light passing through the display panel may also pass through the filler layer 240 and then pass through the lens assembly 230. In addition, the lens 231 in the lens assembly 230 is convex in the third direction (e.g., in the Z-axis direction), but embodiments of the present disclosure are not necessarily limited thereto. In some embodiments, the lenses 231 may be concave, cylindrical, or aspherical to provide various refraction characteristics.

As described above, since a refractive index range of a material having refractive index anisotropy in the lens 231 and a refractive index value of the filler layer 240 are adjusted, the refractive index range can be determined based on the presence or absence of a difference in refractive index between the lens 231 and the filler layer 240. Accordingly, an upper and lower relationship between the lens assembly 230 and the filler layer 240, a convex direction of the lens 231, and other characteristics can be modified.

Each of the first base substrate 210, the second base substrate 220, a third base substrate 260, and a fourth base substrate 270 may include a material through which light may be transmitted, such as glass or plastic.

A polarization control assembly 250 may be formed on a rear surface of the first base substrate 210 or a front surface of the display panel. For example, the polarization control assembly 250 may be disposed between a lower surface of the first base substrate 210 and an upper surface of the display panel (or an upper surface of encapsulation film TFE of the display panel).A polarization control assembly 250 is configured to switch and output 2D image display light of the display panel to a path PDX in the first linear polarization direction or a path PDY in the second linear polarization direction. The polarization control assembly 250 may include a first driving electrode 251, a second driving electrode 252, and driving liquid crystals 254 disposed between the first driving electrode 251 and the second driving electrode 252. The polarization control assembly 250 may further include a polarizing member 257 disposed on the display panel. For example, the polarization control assembly 250 may include first driving electrode 251, driving liquid crystals 254, second driving electrode 252, and polarizing member 257 sequentially stacked.

The polarization control assembly 250 may allow light incident on the path PDX in the first linear polarization direction through the polarizing member 257 to be maintained at and pass through the path PDX in the first linear polarization direction or to be switched to and pass through the path PDY in the second linear polarization direction. Accordingly, the polarization control assembly 250 may selectively maintain or rotate the polarization state of the transmitted light depending on an applied voltage.

The polarization control assembly 250 may allow the light incident on the path PDX in the first linear polarization direction through the polarizing member 257 to be switched to and pass through a path in any linear polarization direction between the first linear polarization direction and the second linear polarization direction.

For example, the first linear polarization direction may be parallel to the first direction (e.g., the X-axis direction) and the second linear polarization direction may be parallel to the second direction (e.g., the Y-axis direction), but an embodiment of the present disclosure is not necessarily limited thereto.

At least some components of the first driving electrode 251, driving liquid crystals 254, second driving electrode 252of the polarization control assembly 250 may be disposed between the third base substrate 260 and the fourth base substrate 270. The polarizing member 257 of the polarization control assembly 250 may be disposed between the display panel and the third base substrate 260. This configuration enables the polarization control assembly 250 to be modularly integrated within the optical stack.

The first driving electrode 251 may be disposed between the third base substrate 260 and the fourth base substrate 270. A voltage may be applied to the first driving electrode 251.

The second driving electrode 252 may be disposed between the third base substrate 260 and the first driving electrode 251. The second driving electrode 252 may be parallel to the first driving electrode 251. A shape of the second driving electrode 252 may correspond to a shape of the first driving electrode 251. A voltage may be applied to the second driving electrode 252. The driving liquid crystals 254 may adjust a linear polarization direction of light based on a voltage difference between the voltage applied to the first driving electrode 251 and the voltage applied to the second driving electrode 252. In some cases, the first driving electrode 251 and the second driving electrode 252 may be patterned in various configurations such as stripe, grid, or pixelated configurations.

The polarizing member 257 may be disposed between the display panel (or an upper surface of encapsulation film TFE of the display panel) and the third base substrate 260. The light emitted from the display panel may vibrate in all directions. The polarizing member 257 may pass only light vibrating in a specific direction among the light emitted from the display panel and block the remaining polarization components. In an embodiment, the polarizing member 257 may pass only light having the path PDX in the first linear polarization direction among the light emitted from the display panel, but embodiments of the present disclosure are not necessarily limited thereto.

The driving liquid crystals 254 may be disposed between the first driving electrode 251 and the second driving electrode 252. The driving liquid crystal 254 may include a liquid crystal that is a birefringent material. An arrangement of the driving liquid crystals 254 may be changed based on the difference between the voltages applied to the first driving electrode 251 and the second driving electrode 252. The driving liquid crystal 254 may be a twisted nematic (TN) liquid crystal.

Referring to FIG. 7, a difference between the voltage applied to the first driving electrode 251 and the voltage applied to the second driving electrode 252 during a two-dimensional image display period may be less than or equal to a predetermined threshold value.

The driving liquid crystal 254 may maintain the linear polarization direction of the light incident with the path PDX in the first linear polarization direction. The light passing through the driving liquid crystal 254 may still have the path PDX in the first linear polarization direction. In some cases, the viewer may perceive a high-resolution two-dimensional image without refractive distortion.

Referring to FIG. 8, a difference between the voltage applied to the first driving electrode 251 and the voltage applied to the second driving electrode 252 during a three-dimensional image display period may be greater than or equal to a predetermined threshold value. The driving liquid crystal 254 may switch the linear polarization direction of the light incident with the path PDX in the first linear polarization direction. The light passing through the driving liquid crystal 254 may have the path PDY in the second linear polarization direction. Accordingly, the viewer may perceive a stereoscopic three-dimensional image from refraction in the lens assembly.

Referring to FIGS. 7 and 8, the first base substrate 210, the second base substrate 220, and the lens assembly 230 may be disposed on the fourth base substrate 270. The lens assembly 230 may be parallel and formed in the shape of a lens sheet. The polarization control assembly 250 may be disposed in a stacked configuration overlapping the lens assembly 230 formed in the shape of the lens sheet.

The lens assembly 230 may include a plurality of lenses 231. In some cases, the lenses 231 may be arranged as a periodic array, a slanted array, or other arrangements to achieve different light field viewing characteristics.

Light passing through the plurality of lenses 231 may experience a refractive index of the lens 231 in the major axis direction, a refractive index of the lens 231 in the minor axis direction, or various refractive indices of the lens 231 in a direction between the major axis direction and the minor axis direction based on an arrangement of birefringent materials (e.g., liquid crystals, slits, etc.) within the plurality of lenses 231. The intermediate refractive indices may be smaller than the refractive index of the lens 231 in the major axis direction and greater than the refractive index of the lens 231 in the minor axis direction, but embodiments of the present disclosure are not necessarily limited thereto. For example, the intermediate refractive indices may also be smaller than the refractive index of the lens 231 in the minor axis direction and greater than the refractive index of the lens 231 in the major axis direction.

In an embodiment, the major axis direction of the lens 231 may be parallel to the second direction (e.g., the Y-axis direction), and the minor axis direction of the lens 231 may be parallel to the first direction (e.g., the X-axis direction). In addition, a refractive index of the filler layer 240 disposed on the lens 231 may be the same as the refractive index of the lens 231 in the minor axis direction and smaller than the refractive index of the lens 231 in the major axis direction, but embodiments of the present disclosure are not necessarily limited thereto. For example, the major and minor axis directions may be oriented at arbitrary angles with respect to the X-axis and Y-axis.

Referring to FIG. 7, light passing through the driving liquid crystal 254 may have the path PDX in the first linear polarization direction, and the first linear polarization direction may coincide with or be parallel to the first direction (e.g., the X-axis direction). Accordingly, the light passing through the driving liquid crystal 254 may experience the refractive index of the lens 231 in the minor axis direction. Since the refractive index of the lens 231 in the minor axis direction is the same as the refractive index of the filler layer 240, the light passing through the driving liquid crystal 254 may travel straight without being refracted at the interface between the lens 231 and the filler layer 240. The two-dimensional image may be displayed from the second type of light field display without refraction. This configuration enables the second type of light field display to provide high-resolution 2D imaging.

Referring to FIG. 8, light passing through the driving liquid crystal 254 may have the path PDY in the second linear polarization direction, and the second linear polarization direction may coincide with or be parallel to the second direction (e.g., the Y-axis direction). Accordingly, the light passing through the driving liquid crystal 254 may experience the refractive index of the lens 231 in the major axis direction. Since the refractive index of the lens 231 in the major axis direction is greater than the refractive index of the filler layer 240, the light passing through the driving liquid crystal 254 may be refracted at the interface between the lens 231 and the filler layer 240. The three-dimensional image may be displayed from the second type of light field display by the refracted light. The refracted light may move toward a first view area V1, a second view area V2, and a third view area V3 based on the mapped viewing angles. Accordingly, the viewer may perceive stereoscopic depth by receiving different image information from each of the first view area V1, the second view area V2, and the third view area V3.

The filler layer 240 may be disposed on the plurality of lenses 231. The second base substrate 220 may be disposed on the filler layer 240. In some cases, the filler layer 240 is disposed between the first base substrate 210 and the second base substrate 220.

The filler layer 240 may include a transparent material through which light can be transmitted. As an example, the filler layer 240 may include an isotropic polymer material.

The refractive index of the filler layer 240 may be the same as a refractive index of the plurality of lenses in the minor axis direction. The refractive index of the filler layer 240 may be smaller than a refractive index of the liquid crystal included in the lens 231 in the major axis direction. Accordingly, light passing through the plurality of lenses 231 may or may not be refracted at the interface.

Referring to FIGS. 5 and 6, in the first type of light field display, the display panel may include a substrate SUB, a thin film transistor layer TFTL, a light emitting element layer EML, and an encapsulation film TFE. Components having substantially the same functions as those of the second type of light field display described above will be denoted by the same reference numerals, and the difference are described. Accordingly, this refractive index relationship allows selective control of refraction based on the polarization state of incident light.

A polarizing member 257 may be disposed between the display panel and a first base substrate 210. The light emitted from the display panel may vibrate in all directions. The polarizing member 257 may pass light vibrating in a specific direction among the light emitted from the display panel and block remaining polarization components. In an embodiment, the polarizing member 257 may pass light having the path PDX in the first linear polarization direction among the light emitted from the display panel, but embodiments of the present disclosure are not necessarily limited thereto.

A third driving electrode 232 may be disposed between the first base substrate 210 and a second base substrate 220, and a fourth driving electrode 233 may be disposed between the first base substrate 210 and the third driving electrode 232. An lens assembly 230 including lenses 231 may be disposed between the third driving electrode 232 and the fourth driving electrode 233. A filler layer 240 may be disposed on the lens assembly 230, but as described above, an upper and lower relationship between the lens assembly 230 and the filler layer 240 is not necessarily limited to that illustrated in FIGS. 5 and 6. In some cases, the filler layer 240 may alternatively be disposed below the lens assembly 230. In one aspect, the first base substrate 210, the fourth driving electrode 233, the lens assembly 230 including lenses 231, the filler layer 240, the third driving electrode 232, and the second base substrate 220 may be sequentially stacked.

Voltages may be applied to the third driving electrode 232 and the fourth driving electrode 233, and the lens 231 may include liquid crystals that are birefringent materials. An arrangement, an alignment direction, and other characteristics, of the liquid crystals in the lens 231 may be changed based on a difference between the voltages applied to the third driving electrode 232 and the fourth driving electrode 233.

Referring to FIG. 5, a difference between the voltage applied to the third driving electrode 232 and the voltage applied to the fourth driving electrode 233 during a two-dimensional image display period may be less than or equal to a predetermined threshold value. Light passing through the display panel may have a path PDX in the first linear polarization direction. The first linear polarization direction may coincide with or be parallel to a minor axis direction of the liquid crystal in the lens 231. Since the light passes through the light crystal experiences a refractive index of the liquid crystal in the minor axis direction and the refractive index of the liquid crystal in the minor axis direction is the same as a refractive index of the filler layer 240, the light might not be refracted at an interface. The two-dimensional image may be displayed from the first type of light field display without refraction. Accordingly, high-resolution two-dimensional images can be displayed by the display device.

Referring to FIG. 6, a difference between the voltage applied to the third driving electrode 232 and the voltage applied to the fourth driving electrode 233 during a three-dimensional image display period may be greater than or equal to a predetermined threshold value. Light passing through the display panel may have a path PDX in the first linear polarization direction. The first linear polarization direction may coincide with or parallel to a major axis direction of the liquid crystal in the lens 231. Since the light passes through the light crystal experiences a refractive index of the liquid crystal in the major axis direction and the refractive index of the liquid crystal in the major axis direction is greater than the refractive index of the filler layer 240, the light may be refracted at the interface. The three-dimensional image may be displayed from the first type of light field display by the refracted light. The refracted light may move toward a first view area V1, a second view area V2, and a third view area V3 based on mapped viewing angles. Accordingly, the viewer may perceive stereoscopic depth information as different image data is directed toward difference viewing areas.

In some cases, the refractive index of the filler layer 240 is the same as the refractive index of the lens 231 or the liquid crystal in the lens 231 in the minor axis direction. The refractive index of the filler layer 240 is smaller than the refractive index of the lens 231 or the liquid crystal in the lens 231 in the major axis direction. In addition, it has been assumed that the linear polarization direction is specified in the first type and the second type of light field displays. In addition, the two-dimensional image is displayed in the first type of light field display when the voltages are not applied to the third driving electrode 232 and the fourth driving electrode 233, and the three-dimensional image is displayed in the first type of light field display when the voltages are applied to the third driving electrode 232 and the fourth driving electrode 233. In addition, the two-dimensional image is displayed in the second type of light field display when the voltages are not applied to the first driving electrode 251 and the second driving electrode 252 and the three-dimensional image is displayed in the second type of light field display when the voltages are applied to the first driving electrode 251 and the second driving electrode 252. These operational illustrate representative driving modes but do not necessarily limit the scope of the present disclosure.

However, this is an example for convenience of explanation, uniformity, and the like, and variables such as a refractive index range based on birefringence characteristics of the liquid crystal, a refractive index value of the filler layer, and a linear polarization direction of light passing through individual components may be further modified to enhance the display quality .

For example, in the first type of light field display, the major axis direction and the minor axis direction of the liquid crystal in the lens 231 may be changed, and in the second type of light display, the linear polarization direction of the light passing through the display panel may be directly changed. For example, the first type light field display achieves switching by modifying the optical axis orientation of the lens, and the second type light field display achieves switching by modifying the polarization state of incident light.

Referring to FIG. 4, in the non-switchable display device (or an always-on display device), a linear polarization direction of light, and an alignment direction of liquid crystals, might not be changed, and a three-dimensional image may be displayed. In the non-switchable display device, the first data may be input to the light emitting element corresponding to the first viewing angle and the light emitting element corresponding to the second viewing angle. The light emitted from the light emitting element corresponding to the first viewing angle is refracted even when the two-dimensional image is displayed, and the light emitted from the light emitting element corresponding to the second viewing angle is also refracted. However, the viewing angles are divided, and resolution two-dimensional image may be less than or equal to 50%, and thus, a resolution deterioration problem may occur. In some cases, in the non-switchable display device, light is always refracted, and thus, a three-dimensional image is displayed.

When a lens 231 and a filler layer 240 are formed between a first base substrate 210 and a second base substrate 220, the filler layer 240 may serve as a frame to the lens 231. The lens 231 is formed by injecting a liquid crystal into the frame of the lens 231 formed by the filler layer 240. For example, the filler layer 240 also determines a frame of a boundary portion of the lens 231.

A surface of the filler layer may be curved so as to be divided into a plurality of lenses 231 as illustrated in FIG. 4. In this case, the boundary portion of the lens 231 are formed (e.g., in a sharp configuration) to divide the plurality of lenses 231.However, such precision may pose a problem during a manufacturing process. The boundary portion between the plurality of lenses 231 may also be relatively bluntly formed due to an error in a process, or the like.

When the boundary portion of the lens 231 is not manufactured to match a specification of the display panel, light passing through the boundary portion from the display panel 110 might not form a refraction angle. This may cause a display quality deterioration problem of displaying a 3D image in the display device.

Embodiments of the present disclosure may include structures and configurations that prevent deterioration of the display quality of the display device even though an error occurs in a manufacturing process of the light field display devices. According to some embodiments, deterioration of the display quality of a three-dimensional image can be prevented or reduced when refraction of light does not occur as designed on a surface where the lens 231 and the filler layer 240 are in contact with each other.

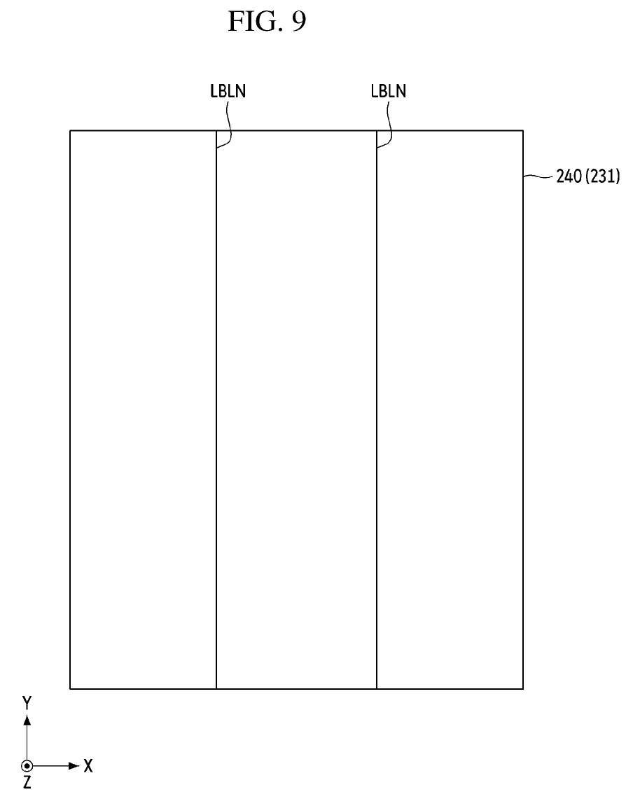

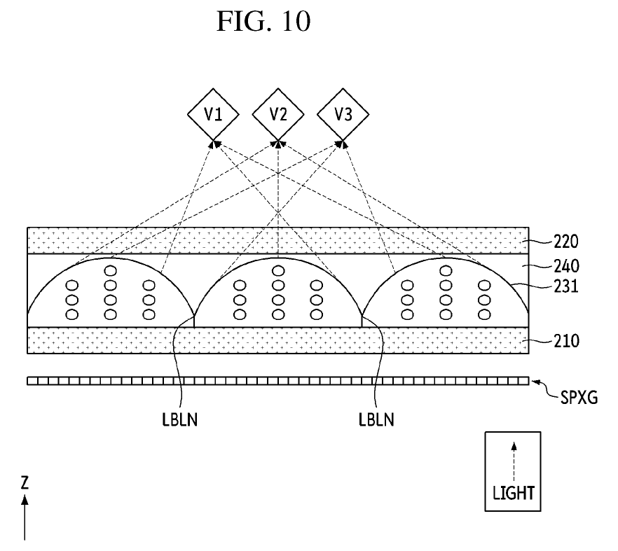

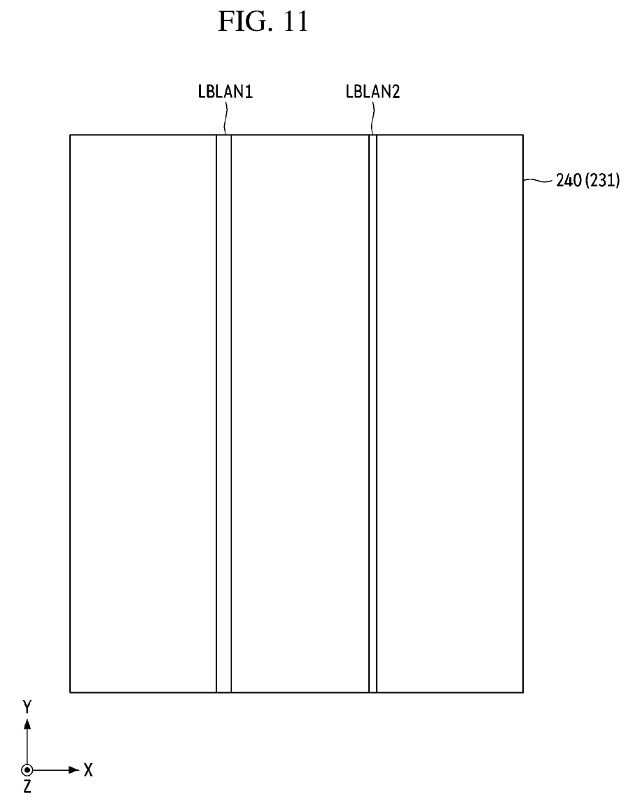

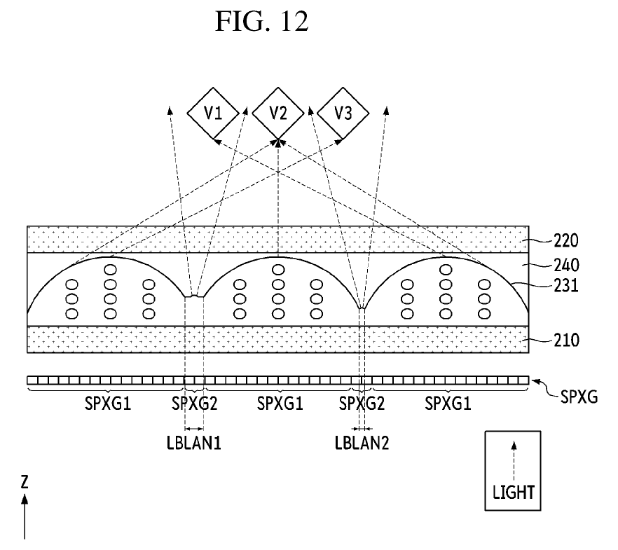

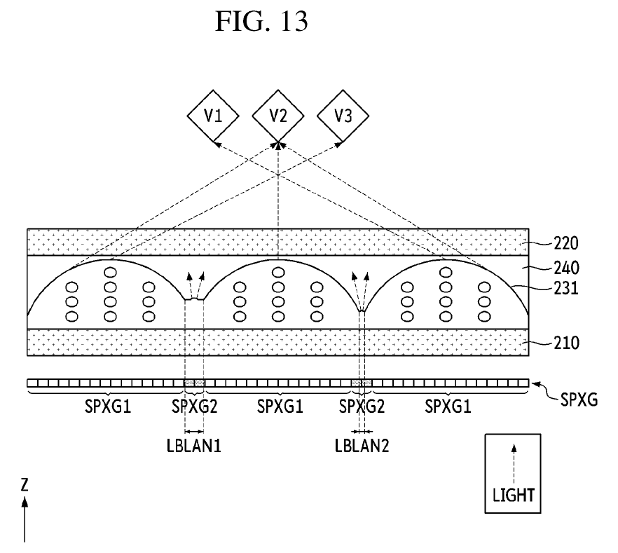

Hereinafter, the boundary portion of the lens 231 is normally formed is described with reference to FIGS. 9 and 10, and the boundary portion of the lens 231 is abnormally formed is described with reference to FIGS. 11 and 12. In some aspects, structures and configurations for preventing deterioration of display quality of a display device when the boundary portion of the lens 231 is abnormally formed are described with reference to FIGS. 13-20. The configuration disclosed herein may be applied to cases where light passing through the abnormally formed boundary portion of the lens 231, regardless of whether the light field display is the switchable display device or the non-switchable display device, and regardless of whether the light field display is the first type of light field display or the second type of light field display.

FIG. 9 is a plan view illustrating a filler layer and a lens including a normally formed boundary portion of the lens. FIG. 10 is a cross-sectional view illustrating the filler layer and the lens including the normally formed boundary portion of the lens.

Referring to FIG. 9, the boundary portion of the lens 231 may include a normal boundary portion LBLN of the lens 231. The normal boundary portion LBLN of the lens 231 may be formed between the plurality of lenses 231. Since the filler layer 240 serves as the frame of the lens 231, the normal boundary portion LBLN may be defined by the filler layer 240 in a plan view. The normal boundary portion LBLN may have a first width in a plan view. In a manufacturing process of the filler layer 240 providing the frame of the lens 231, the filler layer 240 defining the boundary portion of the lens 231 may be formed to have sharp ends toward the first base substrate 210. For example, the width of the normal boundary portion LBLN may be less than a threshold value.

Referring to FIG. 10, light emitted from the display panel may pass through the normal boundary portion LBLN of the lens 231. The display panel may include a sub-pixel group SPXG. The sub-pixel group SPXG may include a plurality of sub-pixels, and the plurality of sub-pixels may include a first sub-pixel displaying a first color, a second sub-pixel displaying a second color, and a third sub-pixel displaying a third color. Each of the first color, the second color, and the third color may be a red color, a green color, and a blue color, and the first color, the second color, and the third color are different from each other. For example, the first color may be a red color, the second color may be a green color, and the third color may be a blue color, but embodiments of the present disclosure are not necessarily limited thereto. The plurality of sub-pixels may further include a fourth sub-pixel displaying a white color. The sub-pixel group SPXG may be configured as an RGB or RGBW arrangement, and each sub-pixel may correspond to an emission area EA1, EA2, or EA3 as described with reference to FIG. 3.

When the three-dimensional image is displayed in the display device, where the lens 231 has the normal boundary portion LBLN, the sub-pixel group SPXG may include a plurality of sub-pixels emitting light passing through the boundary portion of the lens 231. Light emitted from the plurality of sub-pixels within the normally formed boundary portion of the lens 231 may be refracted toward view areas V1, V2, and V3 mapped to the respective sub-pixels while passing through the normal boundary portion LBLN of the lens 231. Because the boundary portion LBLN is sharply formed, refraction occurs consistently, ensuring accurate mapping of sub-pixels to corresponding viewing zones.

However, when the boundary portion of the lens 231 is abnormally formed, light might not be refracted toward the view areas V1, V2, and V3 mapped to the respective sub-pixels. This results in light leakage or crosstalk between viewing zones, thus deteriorating three-dimensional image quality.

FIG. 11 is a plan view illustrating a filler layer and a lens including an abnormally formed boundary portion of the lens. FIG. 12 is a cross-sectional illustrating the filler layer and the lens including the abnormally formed boundary portion of the lens.

Referring to FIG. 11, the boundary portion of the lens 231 may include abnormal boundary portions LBLAN1 and LBLAN2. The abnormal boundary portions LBLAN1 and LBLAN2 of the lens 231 may be formed between the plurality of lenses 231. The abnormal boundary portions LBLAN1 and LBLAN2 may have a second width, which may be greater than the first width of the normal boundary portion LBLN, in a plan view. According to an embodiment, the abnormal boundary portions LBLAN1 and LBLAN2 may appear as a first abnormal boundary portion LBLAN1 (or a first lens boundary portion) and a second abnormal boundary portion LBLAN2 (or a second lens boundary portion). In some cases, the first abnormal boundary portion LBLAN1 and the second abnormal boundary portion LBLAN2 may have different widths, or the same width. During a manufacturing process of the filler layer 240, when the filler layer 240 defining the boundary portion of the lens 231 is bluntly formed, light passing through the boundary portion of the lens 231 might not be directed to the mapped view areas V1, V2, and V3.

Referring to FIG. 12, the sub-pixel group SPXG may include a first sub-pixel group SPXG1 emitting light passing through the lens 231 and a second sub-pixel group SPXG2 emitting light passing through the boundary portion of the lens 231. In some cases, the first sub-pixel group SPXG1 and the second sub-pixel group SPXG2 may be alternatively arranged along the first base substrate 210. The light emitted from the second sub-pixel group SPXG2 may pass through the abnormal boundary portions LBLAN1 and LBLAN2 of the lens 231, and the light emitted from the first sub-pixel group SPXG1 may pass through the lens 231. The abnormal boundary portions LBLAN1 and LBLAN2 of the lens 231 are also portions of the lens 231, but the first sub-pixel group SPXG1 may include the remaining sub-pixels excluding second sub-pixel group SPXG2 among a plurality of sub-pixels included in the sub-pixel group SPXG.

As illustrated in FIG. 12, the second sub-pixel group SPXG2 emitting the light passing through the first abnormal boundary portion LBLAN1 and the second abnormal boundary portion LBLAN2 may be disposed between a plurality of first sub-pixel groups SPXG1. For example, the second sub-pixel groups SPXG2 may overlap the first abnormal boundary portion LBLAN1 and the second abnormal boundary portion LBLAN2 in the thickness direction. However, an embodiment is not necessarily limited thereto, and the second sub-pixel group SPXG2 may correspond to a set of sub-pixels emitting the light passing through the abnormal boundary portions LBLAN1 and LBLAN2.

The light emitted from the second sub-pixel group SPXG2 might not be directed to the mapped view areas V1, V2, and V3, and a refractive angle of the light emitted from the second sub-pixel group SPXG2 may be altered at the first abnormal boundary portion LBLAN1 and the second abnormal boundary portion LBLAN2 due to the abnormal boundary portion. For example, abnormal boundary portion of the lens 231 refers to a boundary region formed between adjacent lenses that deviates from the intended lens profile. For example, the abnormal boundary portion may have a width greater than the width of a normal boundary portion LBLN. When the light emitted from the second sub-pixel group SPXG2 is refracted at a refractive angle other than an original refractive angle due to the collapse of the lens 231 (e.g., when the light emitted from the second sub-pixel group SPXG2 is not refracted and travels straight), display quality of the display device may deteriorate.

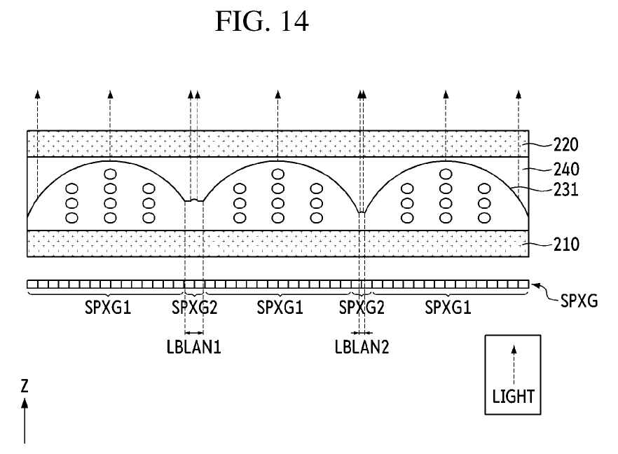

FIG. 13 is a cross-sectional view illustrating a display device configured to display a three-dimensional image according to an embodiment of the present disclosure. FIG. 14 is a cross-sectional view illustrating a display device configured to display a two-dimensional image according to an embodiment of the present disclosure.

Referring to FIG. 13, in an embodiment, luminance of the light emitted from the second sub-pixel group SPXG2 may be lowered. Since the plurality of sub-pixels are assigned to emit corresponding color light, when a magnitude of a data voltage input to each sub-pixel is lowered, intensity of the light emitted from the second sub-pixel group SPXG2 may be reduced. In some cases, an image to be displayed by refracting light is a three-dimensional image. As the luminance is lowered, the image quality of the three-dimensional image of the display device including the first abnormal boundary portion LBLAN1 and the second abnormal boundary portion LBLAN2 may be improved. By reducing luminance of second sub-pixel group SPXG2, the impact of misdirected or non-refracted light passing through abnormal boundary portions can be minimized, thus increase the image quality in three-dimensional image generation.

The present disclosure may improve display quality of the display device by controlling and lowering the luminance of the second sub-pixel group SPXG2 emitting light passing through the abnormally formed boundary portion of the lens 231. In an embodiment, the display driver 120 may apply a modified data voltage to the second sub-pixel group SPXG2 while maintaining original voltage profiles for the first sub-pixel group SPXG1, ensuring consistent color generation while reducing the influence of optical defects.

Referring to FIG. 14, when the two-dimensional image is to be displayed, luminance of the light emitted from the second sub-pixel group SPXG2 may be recovered to original luminance. As described above, when displaying the two-dimensional image, light is not refracted and travels straight, and thus, the collapse of the boundary portion of the lens 231 may not impact the image quality of the two-dimensional image. Accordingly, an original data voltage can be input to the second sub-pixel group SPXG2.

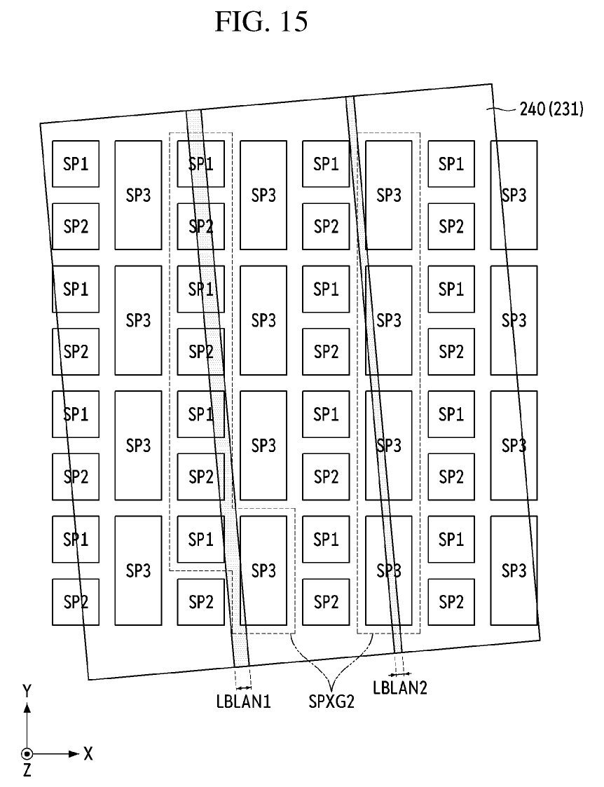

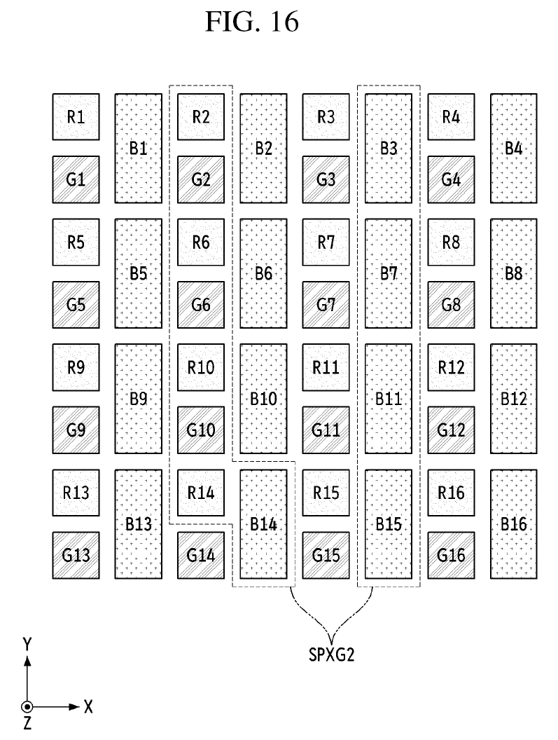

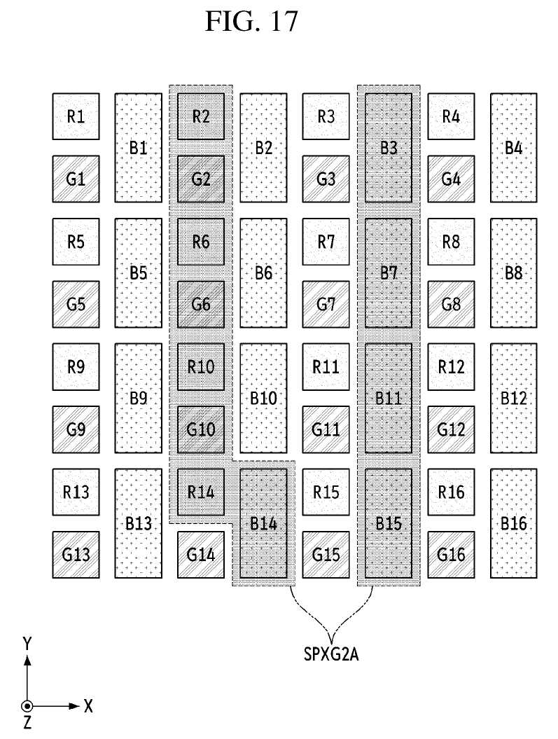

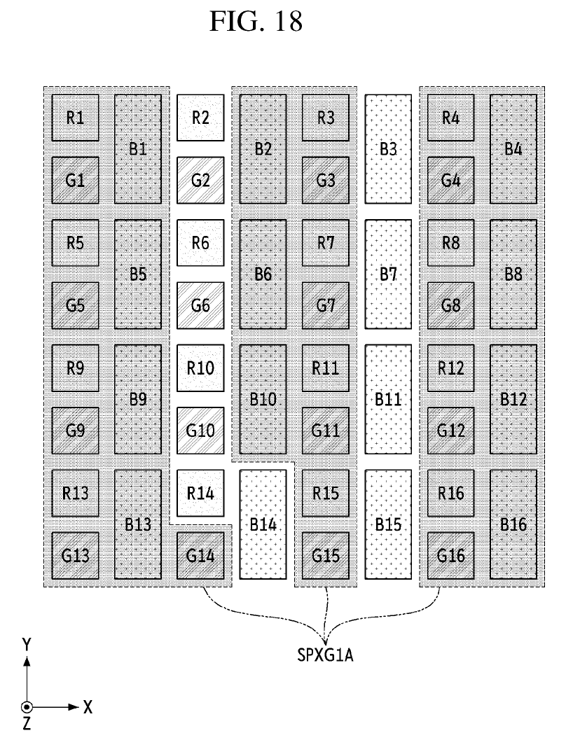

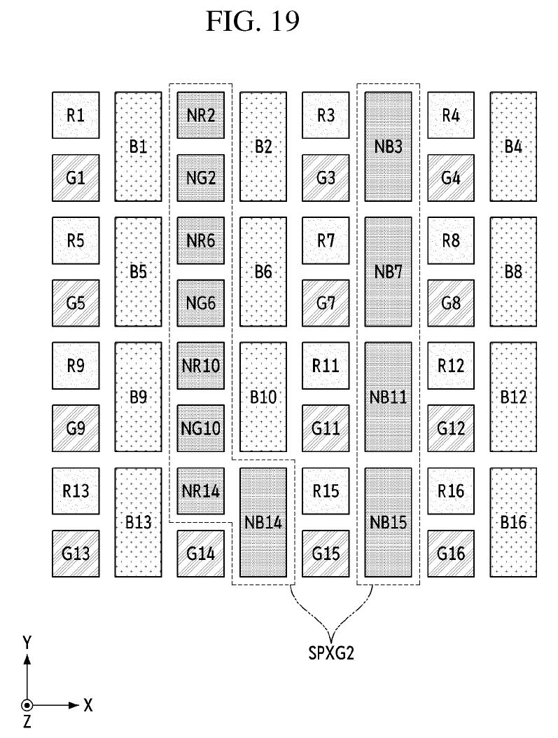

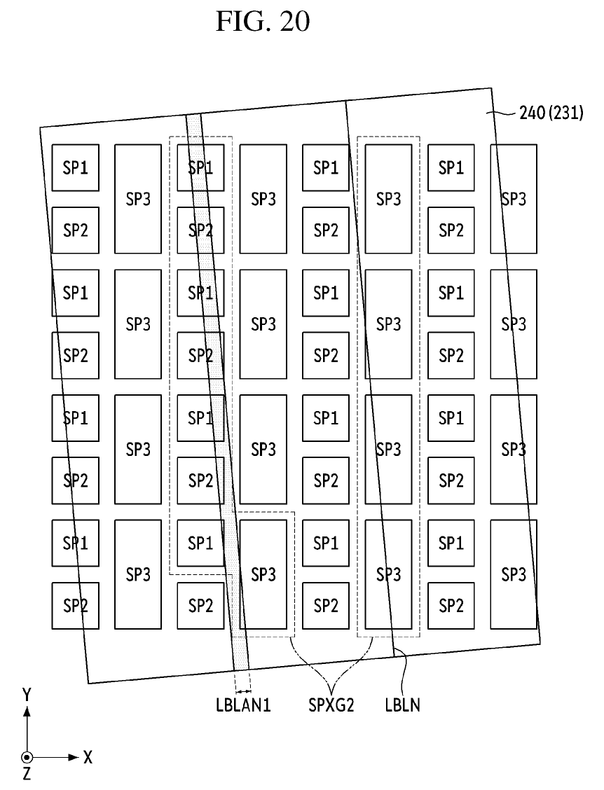

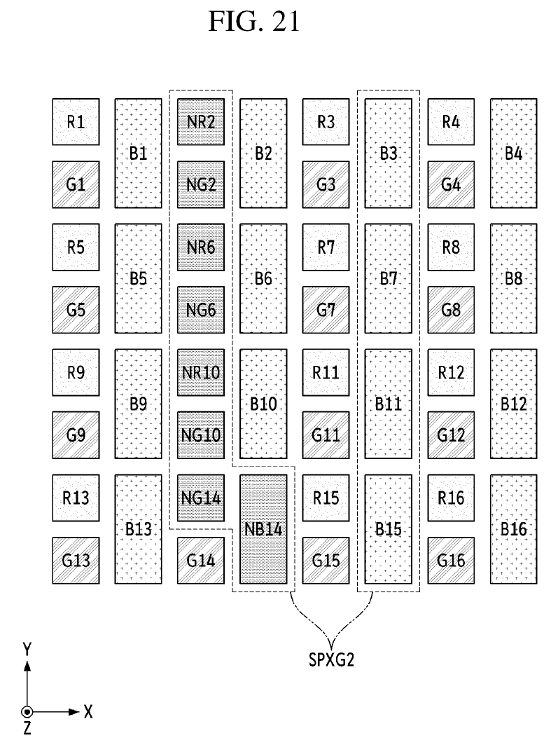

FIG. 15 is a plan view illustrating an overlapping configuration between a sub-pixel group and a boundary portion of a lens according to an embodiment of the present disclosure. FIG. 16 is a plan view illustrating a first data voltage group input to the sub-pixel group. FIG. 17 is a plan view illustrating an area of a second sub-pixel group. FIG. 18 is a plan view illustrating an area of a first sub-pixel group. FIG. 19 is a plan view illustrating a second data voltage group is input to the area corresponding to the second sub-pixel group according to an embodiment of the present disclosure. FIG. 20 is a plan view illustrating an overlapping configuration between a sub-pixel group and a boundary portion of a lens according to an embodiment of the present disclosure. FIG. 21 is a plan view illustrating a first data voltage group and a second data voltage group are input to the area corresponding to the second sub-pixel group according to an embodiment of the present disclosure.

Referring to FIG. 15, second sub-pixel groups SPXG2 may overlap at least a portion of the first abnormal boundary portion LBLAN1 and at least a portion of the second abnormal boundary portion LBLAN2 m. The second sub-pixel groups SPXG2 may overlap the first abnormal boundary portion LBLAN1 and the second abnormal boundary portion LBLAN2 in the third direction (e.g., the Z-axis direction). However, an embodiment of the present disclosure is not necessarily limited thereto, and the second sub-pixel group SPXG2 may be a set of a plurality of sub-pixels emitting light passing through the boundary portion (e.g., the first abnormal boundary portion LBLAN1 and the second abnormal boundary portion LBLAN2) of the lens 231. In some cases, the sub-pixel group SPXG2 may include red, green, or blue sub-pixels based on the pixel arrangement.

In some cases, when an error occurs during a manufacturing process of the display device, a width of the first abnormal boundary portion LBLAN1 (or the first lens boundary portion) may be different from a width of the second abnormal boundary portion LBLAN2 (or the second lens boundary portion). Since the widths of such lens boundary portions are different from each other, the numbers of sub-pixels emitting the light passing through such lens boundary portions (the first lens boundary portion and the second lens boundary portion) may be different from each other. For example, the number (e.g., 8) of sub-pixels arranged in an area SPXG2A where the second sub-pixel group SPXG2 emitting the light passing through the first abnormal boundary portion LBLAN1 is disposed may be different from the number (e.g., 4) of sub-pixels arranged in an area SPXG2A where the second sub-pixel group SPXG2 emitting the light passing through the second abnormal boundary portion LBLAN2 is disposed. However, an embodiment of the present disclosure is not necessarily limited thereto. For example, the first abnormal boundary portion LBLAN1 may overlap a region of the second sub-pixel group SPXG2 having 8 sub-pixels, and the second abnormal boundary portion LBLAN2 may overlap a region of the second sub-pixel group SPXG2 having 4 sub-pixels.

Referring to FIGS. 16-18, the second sub-pixel groups SPXG2 disposed in areas SPXG2A and the first sub-pixel groups SPXG1 disposed areas SPXG1A may be defined. Corresponding data voltages R1, …, R16, G1, …, G16, B1, …, B16 may be input to a plurality of corresponding sub-pixels disposed in the areas SPXG1A where the first sub-pixel groups SPXG1 are disposed and the areas SPXG2A where the second sub-pixel groups SPXG2 are disposed. A first data voltage group may be a set of data voltages R1, …, R16, G1, …, G16, and B1, …, B16 to be be input to the corresponding sub-pixels to display an original image. In some cases, the area SPXG1A may represent unaffected sub-pixel regions corresponding to the plurality of lenses 231, and the area SPXG2A may correspond to sub-pixel regions positioned along first abnormal boundary portion LBLAN1 or second abnormal boundary portion LBLAN2.

The first data voltage group may include first data voltages R1, R3, R4, R5, R7, R8, R9, R11, R12, R13, R15, R16, G1, G3, G4, G5, G7, G8, G9, G11, G12, G13, G14, G15, G16, B1, B2, B4, B5, B6, B8, B9, B10, B12, B13, and B16 input to the areas SPXG1A where the first sub-pixel groups SPXG1 are disposed.

The first data voltage group may include first data voltages R2, R6, R10, R14, G2, G6, G10, B3, B7, B11, B14, and B15 input to the areas SPXG2A where the second sub-pixel groups SPXG2 are disposed. In some cases, the symbol R may represent a data voltage or signal to the sub-pixels to emit a red light, the symbol G may represent a data voltage or signal to the sub-pixels to emit a green light, and the symbol B may represent a data voltage or signal to the sub-pixels to emit a blue light.

Referring to FIG. 19, data voltages of a second data voltage group corresponding to sub-pixels may be input to a plurality of sub-pixels disposed in the areas SPXG2A where the second sub-pixel groups SPXG2 are disposed. The second data voltage group may include a set of data voltages NR2, NR6, NR10, NR14, NG2, NG6, NG10, NB3, NB7, NB11, NB14, and NB15 are updated voltage inputs to lower luminance of light emitted from the second sub-pixel groups SPXG2. The second data voltage group is different from the first data voltage group, where the second data voltage group is adjusted suppressed to prevent optical leakage or scattering caused by abnormal boundary portions LBLAN1 and LBLAN2. In some cases, the voltage (or signal) of the second data voltage group is lower than the voltage (or signal) of the first data voltage group.

The second data voltage group may include second data voltages NR2, NR6, NR10, NR14, NG2, NG6, NG10, NB3, NB7, NB11, NB14, and NB15 input to the areas SPXG2A where the second sub-pixel groups SPXG2 are disposed. By selectively lowering voltages of these sub-pixels while maintaining original voltages in the unaffected area SPXG1A, embodiments of the present disclosure can enhance the display quality in light field display devices.

Referring to FIGS. 16 and 19, image data voltages including a first data voltage group and a second data voltage group may be input to the plurality of sub-pixels disposed in the display device according to an embodiment of the present disclosure.

The respective data voltages as part of the second data voltage group may have different voltage values from the respective data voltages as part of the first data voltage group. For example, the first data voltage group may include data voltages R2, R6, R10, R14, G2, G6, G10, B3, B7, B11, B14, and B15 corresponding to the areas SPXG2A where the second sub-pixel groups SPXG2 are disposed. In addition, the second data voltage group may include data voltages NR2, NR6, NR10, NR14, NG2, NG6, NG10, NB3, NB7, NB11, NB14, and NB15 corresponding to the areas SPXG2A where the second sub-pixel groups SPXG2 are disposed. For example, data voltage values of two data voltage groups are different in order to selectively adjust luminance of the second sub-pixel groups SPXG2 to enhance the display quality.

For example, the second sub-pixel group SPXG2 may include a reference sub-pixel receiving the third and fourth data voltages R2 and NR2. The third data voltage of the first data voltage group or the fourth data voltage of the second data voltage group may be input to the reference sub-pixel. In this case, the data voltage R2 of the first data voltage group is greater than the data voltage NR2 of the second data voltage group. In some cases, for example, in order to lower the luminance of the light emitted from the second sub-pixel group SPXG2, the data voltage R2 is lowered to data voltage NR2 in the second data voltage group.

For example, the second sub-pixel group SPXG2 may include a reference sub-pixel receiving the third and fourth data voltages R6 and NR6. The third data voltage of the first data voltage group or the fourth data voltage of the second data voltage group may be input to the reference sub-pixel. In this case, the data voltage R6 of the first data voltage group is greater than the data voltage NR6 of the second data voltage group, thus reducing light output to suppress crosstalk in the abnormal boundary portions.

For example, the second sub-pixel group SPXG2 may include a reference sub-pixel receiving the third and fourth data voltages R10 and NR10. The third data voltage of the first data voltage group or the fourth data voltage of the second data voltage group may be input to the reference sub-pixel. In this case, the data voltage R10 of the first data voltage group is greater than the data voltage NR10 of the second data voltage group.

For example, the second sub-pixel group SPXG2 may include a reference sub-pixel receiving the third and fourth data voltages R14 and NR14. The third data voltage of the first data voltage group or the fourth data voltage of the second data voltage group may be input to the reference sub-pixel. In this case, the data voltage R14 of the first data voltage group is greater than the data voltage NR14 of the second data voltage group.

For example, the second sub-pixel group SPXG2 may include a reference sub-pixel receiving the third and fourth data voltages G2 and NG2. The third data voltage of the first data voltage group or the fourth data voltage of the second data voltage group may be input to the reference sub-pixel. In this case, the data voltage G2 of the first data voltage group is greater than the data voltage NG2 of the second data voltage group.

For example, the second sub-pixel group SPXG2 may include a reference sub-pixel receiving the third and fourth data voltages G6 and NG6. The third data voltage of the first data voltage group or the fourth data voltage of the second data voltage group may be input to the reference sub-pixel. In this case, the data voltage G6 of the first data voltage group is greater than the data voltage NG6 of the second data voltage group.

For example, the second sub-pixel group SPXG2 may include a reference sub-pixel receiving the third and fourth data voltages G10 and NG10. The third data voltage of the first data voltage group or the fourth data voltage of the second data voltage group may be input to the reference sub-pixel. In this case, the data voltage G10 of the first data voltage group is greater than the data voltage NG10 of the second data voltage group.

For example, the second sub-pixel group SPXG2 may include a reference sub-pixel receiving the third and fourth data voltages B3 and NB3. The third data voltage of the first data voltage group or the fourth data voltage of the second data voltage group may be input to the reference sub-pixel. In this case, the data voltage B3 of the first data voltage group is greater than the data voltage NB6 of the second data voltage group.

For example, the second sub-pixel group SPXG2 may include a reference sub-pixel receiving the third and fourth data voltages B7 and NB7. The third data voltage of the first data voltage group or the fourth data voltage of the second data voltage group may be input to the reference sub-pixel. In this case, the data voltage B7 of the first data voltage group is greater than the data voltage NB7 of the second data voltage group.

For example, the second sub-pixel group SPXG2 may include a reference sub-pixel receiving the third and fourth data voltages B11 and NB11. The third data voltage of the first data voltage group or the fourth data voltage of the second data voltage group may be input to the reference sub-pixel. In this case, the data voltage B11 of the first data voltage group is greater than the data voltage NB11 of the second data voltage group.

For example, the second sub-pixel group SPXG2 may include a reference sub-pixel receiving the third and fourth data voltages B14 and NB14. The third data voltage of the first data voltage group or the fourth data voltage of the second data voltage group may be input to the reference sub-pixel. In this case, the data voltage B14 of the first data voltage group is greater than the data voltage NB14 of the second data voltage group.

For example, the second sub-pixel group SPXG2 may include a reference sub-pixel receiving the third and fourth data voltages B15 and NB15. The third data voltage of the first data voltage group or the fourth data voltage of the second data voltage group may be input to the reference sub-pixel. In this case, the data voltage B15 of the first data voltage group is greater than the data voltage NB15 of the second data voltage group.

As described above, a concept of the reference sub-pixel may be modified, but the data voltage of the first data voltage group and the data voltage of the second data voltage group provided to a specific reference sub-pixel may be different from each other. For example, the data voltage value of the first data voltage group may be greater than the data voltage of the second data voltage group. In some cases, the third data voltage of the first data voltage group may be the same as the first data voltage of the first data voltage group.

Referring to FIGS. 13, 14, 16, and 19, the second sub-pixel group SPXG2 may receive different data voltages when the three-dimensional image is displayed and when the two-dimensional image is displayed. As described above, when the two-dimensional image is displayed, the light might not be refracted, and accordingly, the data voltage input to the sub-pixel might not change. As a result, the display quality might not be compromised.

For example, the second sub-pixel group SPXG2 may receive a data voltage corresponding to the area SPXG2A from the second data voltage group when the three-dimensional image is displayed. The second sub-pixel group SPXG2 may receive a data voltage corresponding to the area SPXG2A from the first data voltage group when the two-dimensional image is displayed. The third data voltage of the first data voltage group and the data voltage of the second data voltage group provided to the reference sub-pixel may be different from each other, and different data voltages may be provided to the second sub-pixel group SPXG2 based on whether the two-dimensional image is to be displayed or the three-dimensional image is to be displayed.

Referring to FIGS. 20 and 21, the example shown may depict second sub-pixel groups SPXG2 overlapping a first abnormal boundary portion LBLAN1 and a normal boundary portion LBLN. The second sub-pixel groups SPXG2 may overlap the first abnormal boundary portion LBLAN1 and the normal boundary portion LBLN in the third direction (e.g., the Z-axis direction). However, an embodiment of the present disclosure is not necessarily limited thereto.

In some cases, when an error occurs in the manufacturing process of the display device, a width of the first abnormal boundary portion LBLAN1 (or a first lens boundary portion) may be different from a width of the normal boundary portion LBLN (or a second lens boundary portion). Since the widths of such lens boundary portions are different from each other, the numbers of sub-pixels emitting the light passing through such lens boundary portions (the first lens boundary portion and the second lens boundary portion) may be different from each other. For example, the number (e.g., 8) of sub-pixels arranged in an area SPXG2A where the second sub-pixel group SPXG2 emitting the light passing through the first abnormal boundary portion LBLAN1 is disposed may be different from the number (e.g., 4) of sub-pixels arranged in an area SPXG2A where the second sub-pixel group SPXG2 emitting the light passing through the normal boundary portion LBLN is disposed. However, an embodiment of the present disclosure is not necessarily limited thereto. For example, the first abnormal boundary portion LBLAN1 may overlap a region of the second sub-pixel group SPXG2 having 8 sub-pixels, and the normal boundary portion LBLN may overlap a region of the second sub-pixel group SPXG2 having 4 sub-pixels.

Even though the three-dimensional image is displayed, data voltages B3, B7, B11, and B15 provided to the sub-pixels arranged in the area SPXG2A where the second sub-pixel group SPXG2 emitting the light passing through the normal boundary portion LBLN is disposed may be the same as the voltages of a first data voltage group. In some cases, the data voltages B3, B7, B11, and B15 of the first data voltage group supplied to the sub-pixels emitting the light passing through the normally formed boundary portion might not deteriorate the display quality. At the same time, data voltages NR2, NR6, NR10, NR14, NG2, NG6, NG10, and NB14 of a second data voltage group may be supplied to the sub-pixels emitting the light passing through the abnormally formed boundary portion may have a reduced voltage.

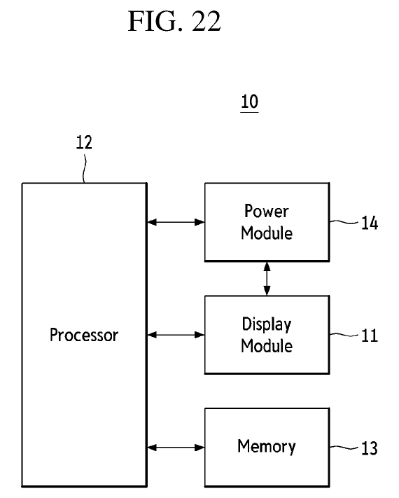

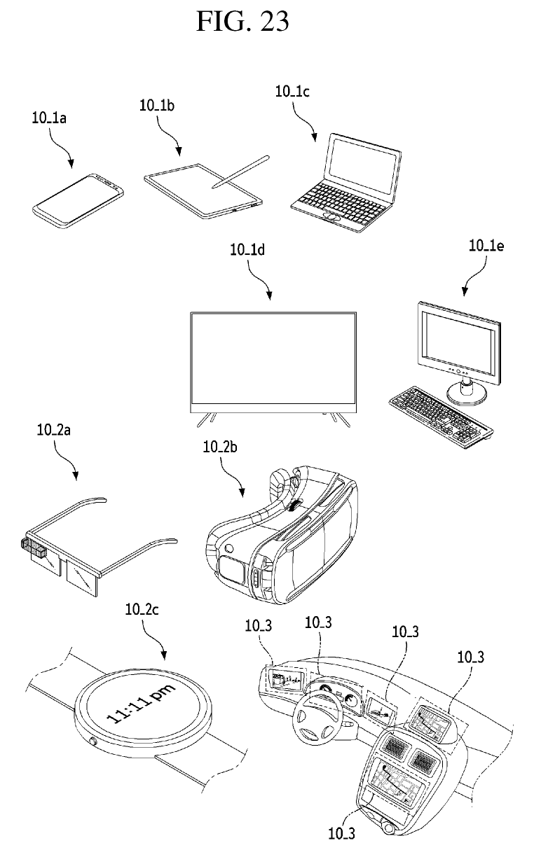

FIG. 22 is a block diagram of an electronic device according to an embodiment of the present disclosure. FIG. 23 is schematic views of electronic devices according to various embodiments of the present disclosure.

Referring to FIG. 22, an electronic device 10 may include a display module 11, a processor 12, a memory 13, and a power module 14. The display module 11 may be substantially the same as the display module 100 described above with reference to FIG. 1. In some cases, the electronic device 10 further includes an input module 15, and output module 16, and a communication module 17.

The processor 12 may include at least one of a central processing unit (CPU), an application processor (AP), a graphic processing unit (GPU), a communication processor (CP), an image signal processor (ISP), and a controller.

The memory 13 may store data information for operating the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device. The power module 14 may include a power conversion module. The power conversion module may convert power from the power supply module to power for operating the electronic device 10.

At least one of the respective components of the above-described electronic device 10 may be included in the display device. In addition, some of individual modules may be included in the display device, and remaining modules may be provided separately from the display device. For example, the display device may include the display module 11, and the processor 12, the memory 13, and the power module 14 may be provided in the form of a separate module within the electronic device.

Referring to FIG. 23, various electronic devices to which the display devices, according to embodiments of the present disclosure, are applied may include image display electronic devices such as a smartphone 10_1a, a tablet computer 10_1b, a laptop computer 10_1c, a television (TV) 10_1d, and a monitor 10_1e for a desktop computer. Furthermore, the electronic devices are applied may include wearable electronic devices including display modules, such as a smart glasses 10_2a, a head mounted display 10_2b, and a smart watch 10_2c. The electronic device may be implemented as vehicle electronic devices 10_3 including display modules, such as a center information display (CID) disposed on an instrument board, a center fascia, or a dashboard of a vehicle and a room mirror display.

Although embodiments of the disclosure have been described above with reference to the accompanying drawings, it will be understood by those having ordinary skill in the technical field to which the disclosure belongs that the disclosure may be practiced in other specific forms without altering the technical idea or essential features of the disclosure. It should therefore be

understood that the embodiments described above are exemplary in all respects and are not necessarily intended to be limiting.

What is claimed is:

1. A display device, comprising:
a display driver configured to output an image data voltage;
a display panel including a plurality of sub-pixels, and configured to receive the image data voltage and to emit light; and
a lens assembly including a plurality of lenses and a lens boundary portion disposed between the plurality of lenses, wherein the plurality of lenses is configured to refract the emitted light,
wherein the image data voltage includes:
a first data voltage group supplying a first data voltage to a first sub-pixel group of the plurality of sub-pixels, respectively, wherein the first sub-pixel group is configured to emit light passing through the plurality of lenses, and
a second data voltage group supplying a second data voltage to a second sub-pixel group of the plurality of sub-pixels, respectively, wherein the second sub-pixel group is configured to emit light passing through the lens boundary portion, and wherein the second data voltage is different from the first data voltage.

2. The display device of claim 1, wherein the first data voltage group includes:
the first data voltage supplied to the first sub-pixel group; and
the first data voltage supplied to the second sub-pixel group.

3. The display device of claim 1, wherein:
the second data voltage group includes the second data voltage supplied to the second sub-pixel group.

4. The display device of claim 1, wherein:
the second sub-pixel group includes a reference sub-pixel, and
a third data voltage supplied to the reference sub-pixel in the first data voltage group is different from a fourth data voltage supplied to the reference sub-pixel in the second data voltage group.

5. The display device of claim 4, wherein:
the third data voltage supplied to the reference sub-pixel in the first data voltage group is greater than the fourth data voltage supplied to the reference sub-pixel in the second data voltage group.

6. The display device of claim 1, wherein:
the lens boundary portion includes a first lens boundary portion and a second lens boundary portion having a different width than a width of the first lens boundary portion.

7. The display device of claim 6, wherein:
the number of sub-pixels disposed in the second sub-pixel group overlapping the first lens boundary portion is different from the number of sub-pixels disposed in the second sub-pixel group overlapping the second lens boundary portion.

8. The display device of claim 6, wherein the first data voltage group includes:
the first data voltage supplied to the first sub-pixel group; and
the second data voltage supplied to the second sub-pixel group overlapping the second lens boundary portion, and
the second data voltage group includes the fourth data voltage supplied to the second sub-pixel group overlapping the first lens boundary portion.

9. The display device of claim 6, wherein the second data voltage group includes:
the fourth data voltage supplied to the second sub-pixel group overlapping the first lens boundary portion; and
the fourth data voltage supplied to the second sub-pixel group overlapping the second lens boundary portion.

10. The display device of claim 1, further comprising:
a first base substrate disposed between the display panel and the lens assembly; and
a second base substrate disposed on and spaced apart from the first base substrate, and
wherein the lens assembly is disposed between the first base substrate and the second base substrate.

11. The display device of claim 10, further comprising:
a filler layer disposed between the first base substrate and the second base substrate.

12. The display device of claim 10, further comprising:
a polarization control assembly disposed between the display panel and the lens assembly, and including a driving liquid crystal configured to adjust a linear polarization direction of light emitted from the display panel.

13. The display device of claim 12, further comprising:
a third base substrate disposed between the display panel and the driving liquid crystal; and
a fourth base substrate disposed between the driving liquid crystal and the first base substrate.

14. The display device of claim 13, wherein the polarization control assembly further includes:
a first driving electrode disposed between the driving liquid crystal and the fourth base substrate; and
a second driving electrode disposed between the third base substrate and the driving liquid crystal.

15. The display device of claim 1, wherein:
the second sub-pixel group is configured to receive the first data voltage group including the first data voltage to display supplied to a two-dimensional image, and
the second sub-pixel group is configured to receive the second data voltage group including a fourth data voltage to display supplied to a three-dimensional image.

16. An electronic device, comprising:
a processor configured to provide an image signal;
a display module configured to receive the image signal and to display an image; and
a power module configured to supply power to the display module,
wherein the display module includes:
a display driver configured to output an image data voltage;
a display panel including a plurality of sub-pixels, and configured to receive the image data voltage and to emit light; and
a lens assembly including a plurality of lenses and a lens boundary portion disposed between the plurality of lenses, wherein the plurality of lenses is configured to refract the emitted light,
the image data voltage includes:
a first data voltage group supplying a first data voltage to a first sub-pixel group of the plurality of sub-pixels, respectively, wherein the first sub-pixel group is configured to emit light passing through the plurality of lenses, and
a second data voltage group supplying a second data voltage to a second sub-pixel group of the plurality of sub-pixels, respectively, wherein the second sub-pixel group is configured to emit light passing through the lens boundary portion, and wherein the second data voltage is different from the first data voltage.

17. The electronic device of claim 16, wherein the first data voltage group includes:
the first data voltage supplied to the first sub-pixel group; and
the second data voltage supplied to the second sub-pixel group, and
the second data voltage group includes the second data voltage supplied to the second sub-pixel group.

18. The electronic device of claim 16, wherein:
the lens boundary portion includes a first lens boundary portion and a second lens boundary portion having a different width than a width of the first lens boundary portion.

19. The electronic device of claim 16, wherein the display module further includes:
a first base substrate disposed between the display panel and the lens assembly; and
a second base substrate disposed on and spaced apart from the first base substrate, and
the lens assembly is disposed between the first base substrate and the second base substrate.

20. The electronic device of claim 16, wherein:
the second sub-pixel group is configured to receive the first data voltage group including the first data voltage to display a two-dimensional image, and
the second sub-pixel group is configured to receive the second data voltage group including a fourth data voltage to display a three-dimensional image.
